(19) United States
(12) Patent Application Publication
(10) Pub. No.: US 2025/0141181 A1
(43) Pub. Date: May 1, 2025

(54) FREQUENCY-CHIRPED SILICON PHOTONIC LASERS

(71) Applicant: OpenLight Photonics, Inc., Goleta, CA (US)

(72) Inventors: John Parker, Goleta, CA (US); Molly Piels, Santa Barbara, CA (US); Erik Johan Norberg, Santa Barbara, CA (US)

(21) Appl. No.: 18/383,759

(22) Filed: Oct. 25, 2023

(51) Int. Cl. H01S 5/026; G02F 1/01; G02F 1/025; H01S 5/068

(52) U.S. Cl. CPC H01S 5/026; G02F 1/0147; G02F 1/025; H01S 5/06821; G02F 2202/105; G02F 2203/055

(57) ABSTRACT

A frequency-chirped integrated silicon-photonic laser may be provided with separate gain and phase-tuning sections in the laser cavity, one or two wavelength filters forming part of the reflective structures defining the cavity, and electro-optic and optionally thermo-optic intra-cavity and filter phase tuners. The electro-optic phase tuners may be driven with synchronized voltage waveforms, at amplitudes determined, based on measurements of the laser output power and chirp, to achieve mode-hop-free frequency chirping with a target chirp amplitude. The waveforms may be predistorted to improve chirp linearity.

### BACKGROUND

Frequency-tunable lasers are employed in various sensing applications, including, for example, frequency modulated continuous wave (FMCW) Lidar and optical coherence tomography (OCT). However, existing lasers commonly used for these purposes suffer from various drawbacks and limitations. Accordingly, alternative lasers for Lidar and other applications are desirable.

### BRIEF DESCRIPTION OF THE DRAWINGS

Described herein, with reference to the accompanying drawings, are frequency-chirped integrated silicon photonic lasers and associated methods of calibration and control.

FIGS. 1A-1C are conceptual drawings illustrating general relations between the laser cavity modes, gain spectrum, and filter spectrum of lasers with different types of optical wavelength filters.

FIG. 2A is a conceptual block diagram of an example chirped laser with tunable ring-resonator-based optical filters, in accordance with one embodiment.

FIG. 2B is a structural schematic of the example chirped laser of FIG. 2A.

FIGS. 2C and 2D are structural schematics of alternative example chirped lasers with tunable ring-resonator-based optical filters, in accordance with various embodiments.

FIG. 3 is a top view of an example layout of the chirped laser with tunable ring-resonator-based optical filters of FIGS. 2A and 2B.

FIGS. 4A and 4B are schematic transverse cross sections of the chirped laser with tunable ring-resonator-based optical filters in the example layout of FIG. 3 at locations of III-V diode structures and thermo-optic phase tuners, respectively.

FIG. 5A is a conceptual block diagram of an example chirped laser with grating-based optical filters, in accordance with various embodiments.

FIGS. 5B-5D are structural schematics of example lasers constituting various embodiments of the example chirped laser of FIG. 5A.

FIGS. 6A-6C are schematic longitudinal cross sections of the example chirped lasers with grating-based optical filters of FIGS. 5A-5D at locations of electro-optic and thermo-optic phase tuners.

FIG. 7 is a graph illustrating the simulated laser output power as a function of wavelength shift for a chirped laser in accordance with one example embodiment.

FIGS. 8A and 8B are graphs conceptually showing waveforms of the laser output power before and after amplification in accordance with one example embodiment.

FIG. 9 is a block diagram of an example chirped laser system in accordance with various embodiments.

FIGS. 10A-10C are graphs illustrating the calibration of electro-optic tuners in the chirped laser based on negative spikes in laser output power during a chirp, in accordance with various embodiments.

FIGS. 11A and 11B are graphs illustrating measurements of laser chirp via a balanced photocurrent at the output of an interferometric wavelength monitor, in accordance with various embodiments.

FIGS. 12A and 12B-12C are graphs of example initial and predistorted voltage waveforms applied to the electro-optic tuners of the chirped laser and the resulting chirp profiles, respectively, illustrating linearization of the chirp in accordance with various embodiments.

FIGS. 13A and 13B are flowcharts illustrating an example method of calibrating a chirped laser system, in accordance with various embodiments.

FIG. 14 is a flowchart illustrating an example method of operating a calibrated chirped laser system, in accordance with various embodiments.

### DESCRIPTION

Described herein are frequency-chirped silicon photonic lasers, e.g., for Lidar applications and other applications with similar laser requirements. Among the broader category of lasers with tunable frequency or, equivalently, tunable wavelength, “frequency-chirped” (or simply “chirped”) lasers as understood herein are lasers designed for frequency tuning at a high rate (e.g., greater than 100 MHz/μs) over a narrow range (e.g., on the order of or less than 1 nm at visible or near-infrared wavelengths), as compared with common widely tunable lasers for other applications, which can achieve tuning ranges of tens or hundreds of nanometers, but at much slower tuning rates.

For high-performance sensing with chirped lasers, a narrow spectral linewidth and rapid tunability are generally desired. For example, in Lidar imaging systems, a laser linewidth of less than 400 kHz is needed to measure long-range targets at distances of more than 100 m, and tunability over a 1-100 GHz range within 1-100 μs with a highly linear slope (measured in GHz/s) is desirable to achieve good depth resolution.

Distributed feedback (DFB) lasers, as are commonly used in Lidar applications, can be tuned rapidly, or “chirped,” via the laser drive current, but achieve only medium chirp ranges, typically less than 3 GHz at 1 μs chirp times, with a few results as large as 20 GHz at chirp times greater than 100 μs (corresponding to significantly slower chirp rates). Additionally, DFB lasers suffer from a broad spectral linewidth, which can be reduced to less than 400 kHz with custom grating designs, or by external optical feedback circuitry, but at the cost of significantly increased cost and/or size. Apart from these performance limitations, DFB lasers have drawbacks owing to their operating principle, that is, the generation of the laser chirp by modulating the laser drive current. One problem is that there is a highly nonlinear relationship between laser drive current and laser frequency chirp due to current conversion to carrier density and heat, and also varying time constants through the chirp modulation. This effect leads to degraded chirp linearity, requiring a highly pre-distorted electrical modulation signal to correct the nonlinearity. Another downside of generating the chirp in optical frequency by modulating the laser drive current is that the laser output power varies along with the frequency. This effect reduces the Lidar range when the optical power is low and increases laser relative intensity noise (RIN) due to the large power modulation during the chirp. Accordingly, alternative lasers for Lidar and other applications are desirable.

In contrast with many prior-art Lidar lasers, the chirped lasers described herein include separate gain and phase-tuning sections within the laser cavity, achieving a decoupling of the optical frequency of the laser from the output power of the laser. The laser cavity is defined between two at least partially reflective structures that also implement an optical wavelength filter, or pair of optical wavelength filters, to select a single cavity mode for lasing by ensuring that all but one of the generally multiple cavity modes within the gain spectrum of the gain section incur losses in excess of the gain. A single cavity mode is selected if the filter spectrum (or, more precisely, the range of wavelengths for which the gain in the gain section exceeds the total filter losses during a roundtrip through the cavity) is narrower than the cavity mode spacing. The phase-tuning section within the laser cavity forms part of an electro-optic intra-cavity phase tuner that facilitates rapid tuning of the laser frequency. To enable aligning the cavity mode with the filter spectrum of the optical wavelength filter(s), the optical filter(s) are themselves equipped with phase tuners. These filter phase tuners may include low-speed thermo-optic tuners, which allow shifting the filter spectrum to compensate, e.g., for temperature changes or manufacturing deviations from the filter design. Alternatively or additionally, the filter phase tuners may include high-speed electro-optic phase tuners, which allow the filter spectrum to be swept along with the selected cavity mode for mode-hop-free frequency tuning across a larger tuning range (or, synonymously, “laser chirp range”). With the slower thermo-optic filter phase tuners alone, the laser high-speed tuning range using the electro-optic intra-cavity phase tuner is limited to the filter spectrum (provided it is smaller than the cavity mode spacing), but with electro-optic filter phase tuners synchronized with the electro-optic intra-cavity phase tuner, the achievable laser tuning range extends as far as the tuning range of the intra-cavity phase tuner (also “tuner chirp range”) itself.

The described silicon photonic lasers are generally implemented in a hybrid material platform, where optically active regions, such as the gain section in the laser cavity and optionally the electro-optic intra-cavity and/or filter phase tuners, are formed in compound semiconductor material—typically III-V material—bonded to a patterned silicon-on-insulator (SOI) wafer. The laser cavity may be implemented as a hybrid waveguide, e.g., including a silicon waveguide and III-V waveguide section(s) disposed thereabove, bounded by reflective structures implemented in the silicon layer. The reflective structures may include combinations of Bragg gratings, ring resonators, and/or partial reflectors such as waveguide loop reflectors. Thermo-optic phase tuners may be implemented by heaters disposed above the silicon waveguides, and allow slow wavelength tuning via adjustments of the heater current. Electro-optic phase tuners may be implemented in the silicon layer as forward-biased or reverse-biased p-n junctions, or in the III-V (or other compound semiconductor) layer as forward-biased or reverse-biased p-n or p-i-n junctions, and facilitate chirping the laser frequency by applying a swing voltage around the bias voltage.

The Bragg gratings and ring resonators generally double as the wavelength-selective filters. While the filter spectrum of a Bragg grating is characterized by a single central reflective filter peak, with side lobes of much smaller reflection amplitude, ring resonators have a periodic filter spectrum with filter peaks of comparable magnitude separated by the free spectral range (FSR) of the filter. Such a periodic filter can result in multiple lasing cavity modes. To circumvent this problem and select a single cavity mode, two ring resonator filters with slightly different FSRs may be used in conjunction to create a larger effective FSR, exploiting the Vernier effect. Beneficially, ring resonator filters are easier to implement in silicon, as they allow for feature sizes greater than 200 nm, which can be fabricated using standard and low-cost 248-nm deep ultra-violet (DUV) photolithography. Bragg gratings, by comparison, are typically made with feature sizes around 100 nm, which generally require the use of more expensive DUV phase shift masks in conjunction with computer simulations to calculate lithographic corrections, or more advanced lithography techniques such as immersion lithography or electron beam lithography. Also, for a given FWHM of the wavelength filter, ring resonator filters, due to resonant effects, take up a smaller area than grating filters. Further, ring resonators enable narrower optical linewidth to be achieved with the same cavity length because the resonant effects in the ring increase the photon lifetime in the laser cavity: in every cavity round-trip, the light circulates multiple times through a ring resonator, but only once through a grating, thus increasing the photon lifetime for low-loss ring-based designs, which reduces optical linewidth.

In addition to the silicon photonic lasers themselves, associated control circuitry and control methods employed during operation and calibration are also described herein by example. In particular, various embodiments provide means for synchronizing and matching the phase shifts applied by the intra-cavity and filter phase tuners to maintain alignment between the selected cavity mode and the filter spectrum during tuning, as well as for maintaining a linear chirp profile and high output power uniformity across the chirp. Synchronized and matching phase shifts are achieved by applying swing voltages to the intra-cavity and filter phase tuners with synchronized approximately triangular waveforms and an amplitude ratio that is the inverse of a calibrated ratio of the tuning efficiencies of the tuners. The tuning efficiencies of the intra-cavity and filter tuners can be measured during calibration one at a time—that is, holding one tuner at a constant voltage and tuning the other—by monitoring the laser output power as the cavity mode is tuned relative to the filter spectrum, and counting the number of negative spikes in the laser output power, corresponding to mode hops, during tuning. Mode hops are abrupt jumps from one cavity mode to another as the former mode loses alignment with the filter spectrum and its losses increase beyond the losses incurred by the latter mode. Once the relative waveform amplitudes of the intra-cavity and filter tuners have been calibrated, the waveform amplitudes can be scaled to achieve the desired chirp amplitude (that is, maximum frequency shift between the extrema of the chirped signal). For this purpose, the frequency of the chirped signal can be measured as a function of time based on the balanced photocurrent at the output of an interferometric wavelength monitor, which cross zero at constant frequency intervals. The chirp measurement is also used, in various embodiments, to measure chirp linearity and determine a predistorted voltage waveform that corrects for any nonlinearity. Variations in laser output power incidental to chirping can be compensated, at least in part, by driving an amplifier at the laser output with a suitable waveform.

The foregoing examples of various aspects and features of the disclosed subject matter will become more readily understood from the following detailed description of the accompanying drawings.

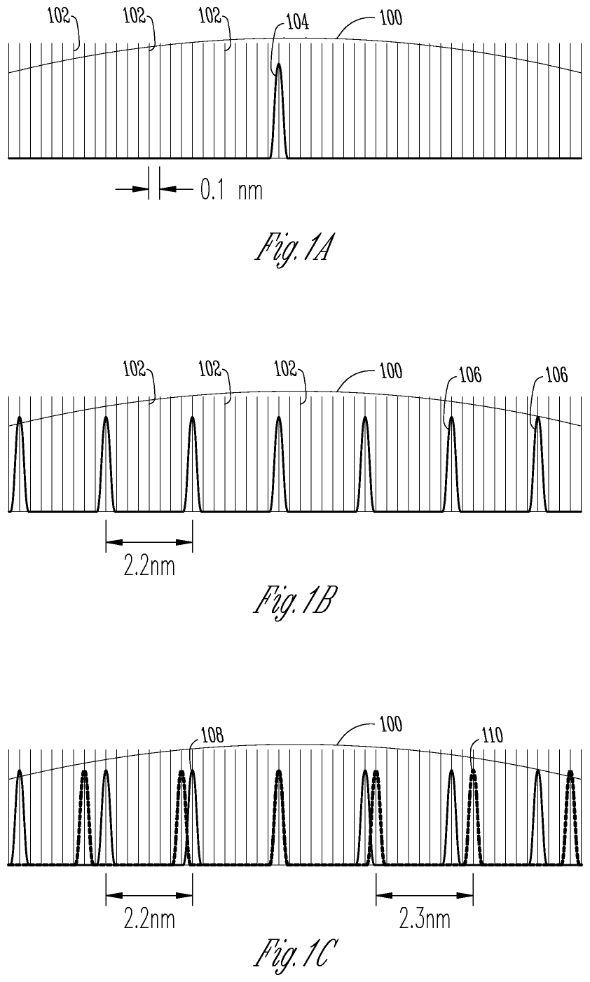

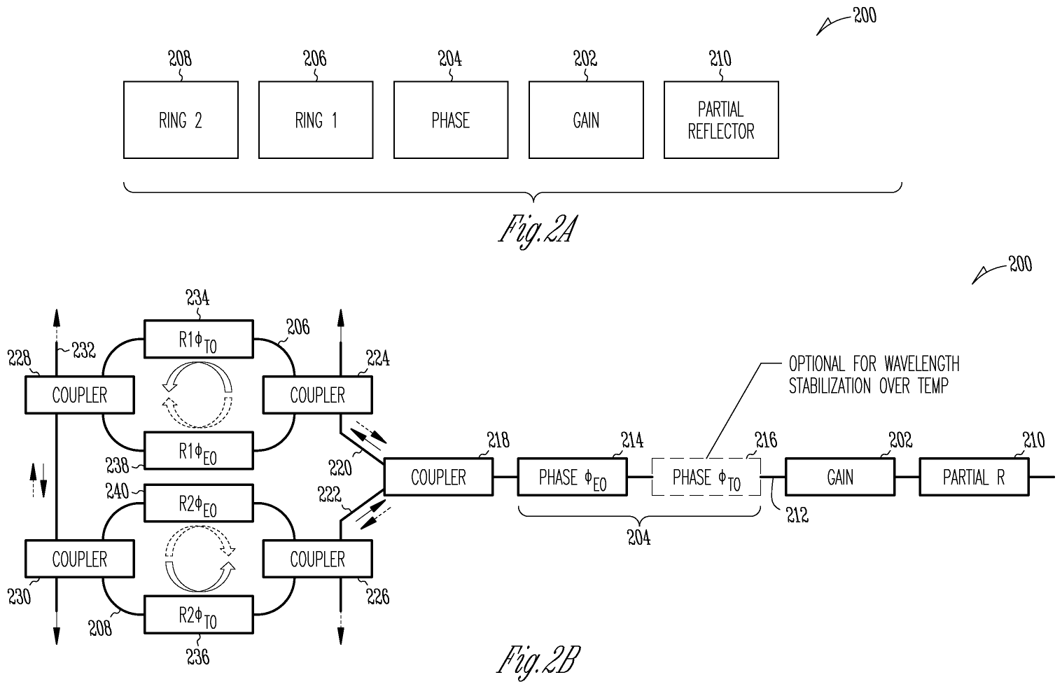

FIGS. 1A-1C are conceptual drawings illustrating general relations between the laser cavity modes, gain spectrum, and filter spectrum of lasers with different types of optical wavelength filters. The gain spectrum 100 corresponds to the range of wavelengths that are emitted and amplified in the gain section of the laser. As described below, the gain section may be implemented, for example, by a III-V diode structure, which may have a gain spectrum with a full width at half maximum (FWHM) on the order of tens of nanometers around a center wavelength in the near infrared regime (e.g., 1550 nm in the C-band or 1310 nm in the O-band of the telecom windows commonly used in optical communications). At 1550 nm, an FWHM of 70 nm corresponds to about 9 THz. The cavity modes 102 of the laser form a “comb” of modes at wavelengths that meet the condition that the length of the cavity is an integer multiple of half the wavelength; these modes are spaced at equal frequency intervals and, because the cavity length is much greater than the wavelength, near-equal wavelength intervals. At a wavelength of 1550 nm, a silicon laser cavity having a length of about 3 mm (with a modal group refractive index of about 3.6) results in a cavity mode spacing of about 0.1 nm. Thus, the gain spectrum encompasses many cavity modes 102.

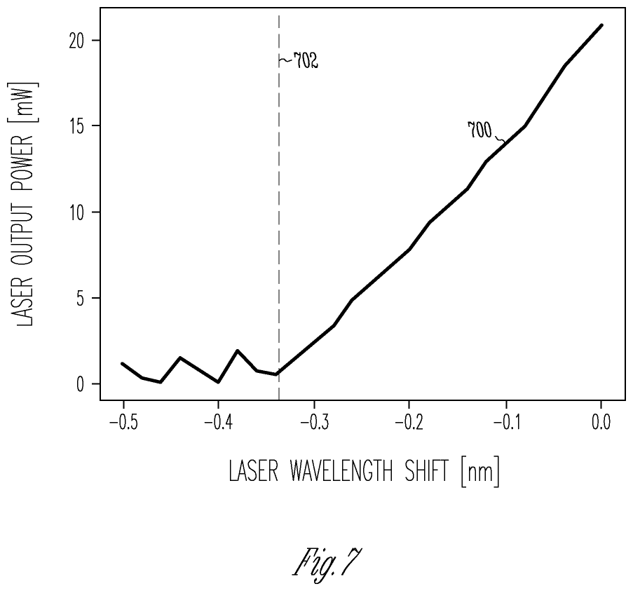

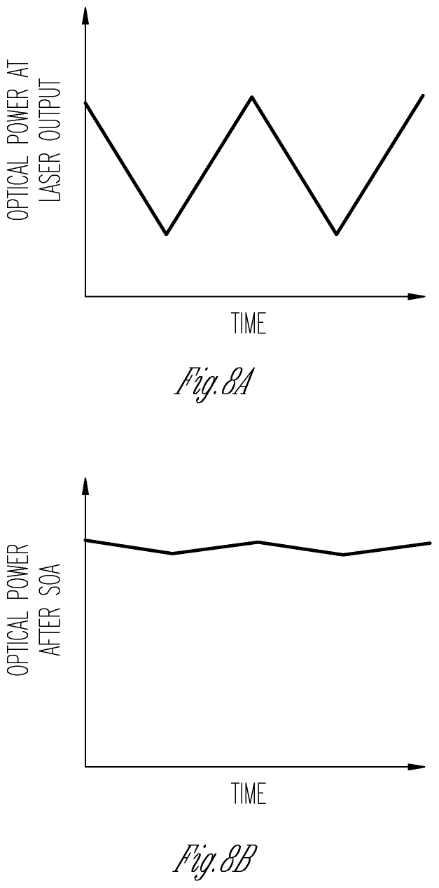

FIG. 1A conceptually illustrates the use of a wavelength filter to select a single cavity mode for lasing. As depicted, the filter spectrum 104 of the wavelength filter has a single transmission peak (not counting side lobes of lower transmission amplitude) with a spectral width smaller than the cavity mode spacing. Cavity modes outside the narrow transmission peak incur losses in excess of the gain in the gain section, and are thus suppressed, leaving a single cavity mode overlapping with the transmission peak that will lase, that is, be sustained in the laser cavity. (Note that, in this context, the “spectral width” is understood as the width of the wavelength range surrounding the transmission maximum for which gain exceeds loss, which may be slightly larger or smaller than the FWHM of the filter spectrum, depending on the gain.) A suitable filter spectrum 104 can be created, e.g., with a Bragg grating etched into a waveguide in which the cavity is formed, as explained below with reference to FIG. 6A.

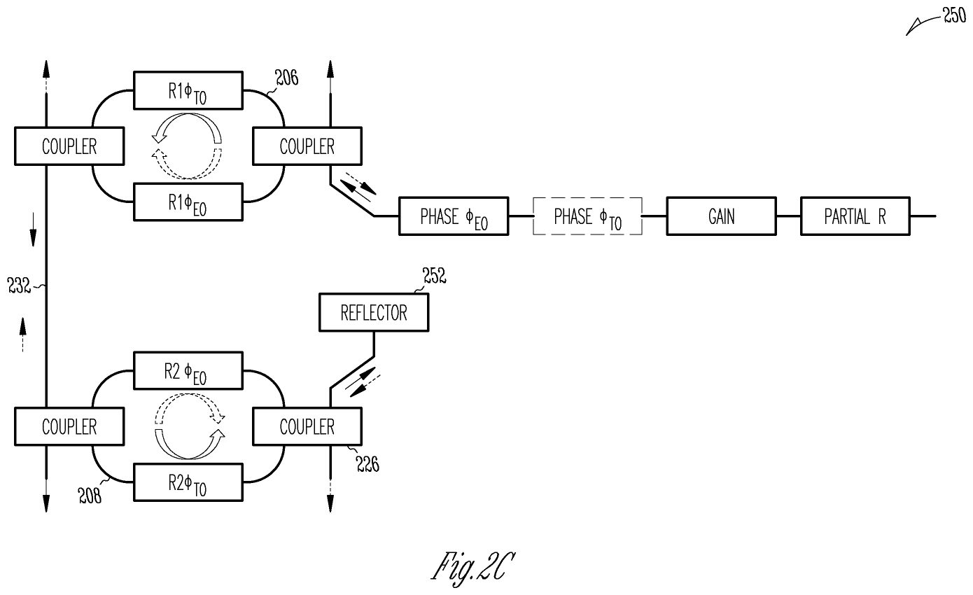

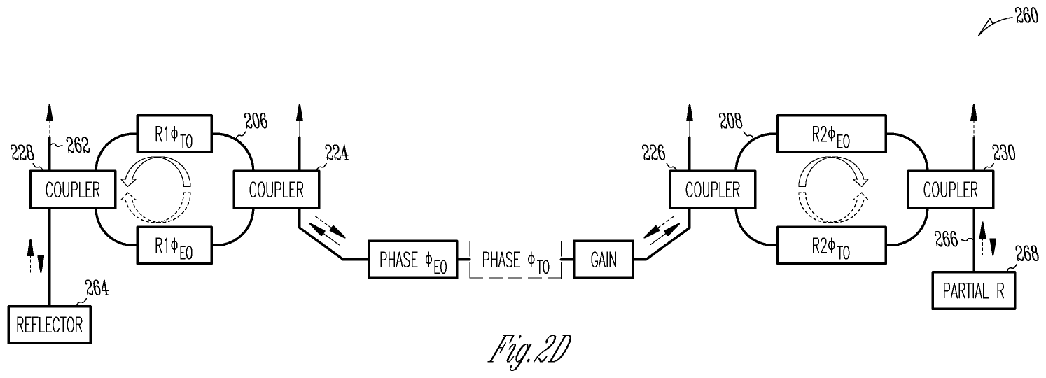

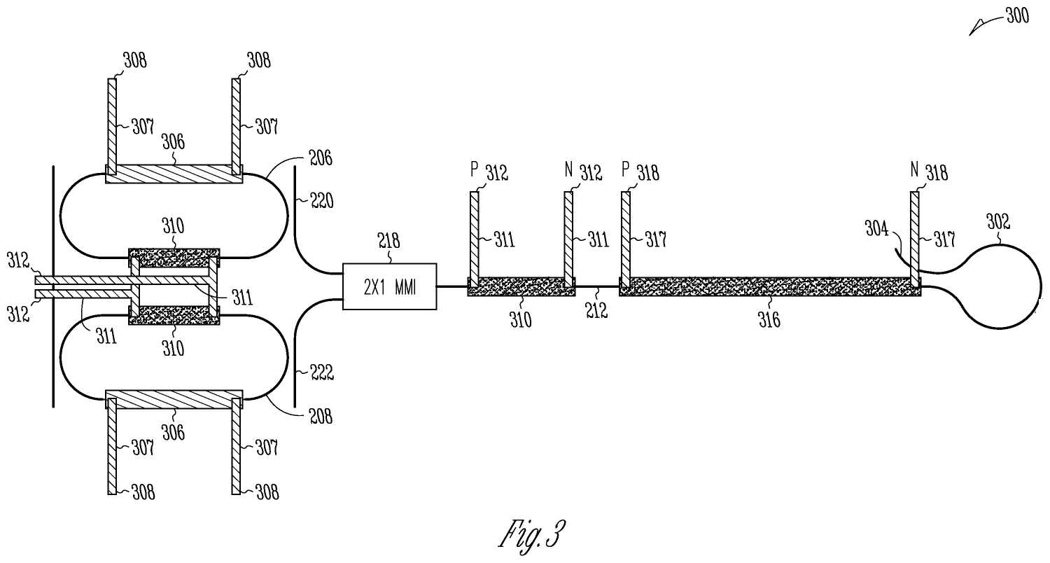

FIG. 1B conceptually illustrates the operation of a wavelength filter with a periodic filter spectrum 106 including multiple transmission peaks at equal frequency intervals, corresponding to near-equal wavelength intervals, referred to as the FSR of the filter. Such a filter spectrum 106 can be created with resonant structures such as ring resonators, e.g., as described below with reference to FIGS. 2B and 3. While each individual transmission peak may be sufficiently narrow to select a single cavity mode, the FSR of the filter may be significantly smaller than the width of the gain spectrum 100, as shown, resulting in the selection of multiple cavity modes for lasing. For example, in the vicinity of 1550 nm, a silicon ring filter with a diameter of 90 μm has resonances (corresponding to transmission peaks) spaced at an FSR of about 2.2 nm (modal group refractive index around 3.9). Within a gain spectrum of 70 nm, that results in over thirty cavity modes that are not suppressed. While the FSR of a ring filter can be decreased by decreasing the size of the ring, manufacturing imposes practical lower limit on the achievable dimensions. To increase the FSR to 70 nm, for instance, the ring diameter would have to be decreased to about 3 μm, which results in very high optical radiation and scattering losses for the light. Also the wavelength filter FWHM increases with such a small ring, becoming too broad to select a single laser cavity mode.

FIG. 1C conceptually illustrates the use of two wavelength filters with slightly detuned periodic filter spectra 108, 110 to select a single cavity mode for lasing. “Slightly detuned,” in this context, means that the FSRs of the two filters differ by a small relative amount. As a result, if two transmission peaks from the two filters are aligned in wavelength, their respective nearest-neighbor transmission peaks are slightly misaligned, the next-nearest-neighbor transmission peaks are slightly more misaligned, and so on. Realignment occurs only after a large number of transmission-peak intervals. For example, with two rings having FSRs of 2.2 nm and 2.3 nm, the peaks are aligned only every approximately 50 nm. Since the two filters together transmit light only at wavelengths where each of them transmits, the transmission peaks of the combined spectrum of the two filters occur only where the transmission peaks of both filters overlap, that is, every 50 nm in the above example. That is, the effective FSR of the combined filters is substantially increased compared to the individual FSRs—a phenomenon commonly known as the Vernier effect. Taking advantage of the Vernier effect, a pair of ring filters can easily achieve an FSR greater than the width of the gain spectrum, and thus enable selection of a single cavity mode, at practically achievable ring dimensions.

FIG. 2A is a conceptual block diagram of an example tunable laser 200 with tunable ring-resonator-based optical filters, in accordance with one embodiment. The tunable laser 200 includes an optical gain section 202 and a phase-tuning section 204 placed between a pair of optical ring resonators 206, 208 on one end and a partial reflector 210 on the other end. The partial reflector 210 and the ring resonators 206, 208 define the boundaries of the laser cavity and, together with the laser cavity, form the laser resonator. A portion of the laser light amplified in the cavity is transmitted by the partial reflector 210, which serves, accordingly, as the laser output. The ring resonators 206, 208 are configured as a wavelength filter to select a single cavity mode for lasing, using the Vernier effect as described above.

FIG. 2B is a structural schematic of the example tunable laser 200 of FIG. 2A. As FIG. 2B illustrates in more detail, the partial reflector 210, gain section 202, and phase-tuning section 204 are formed along an optical waveguide 212, which provides the medium in which the laser cavity is formed and is hereinafter also referred to as the “cavity waveguide” 212. In other words, the laser resonator is implemented as a waveguide resonator. The phase-tuning section 204 includes an electro-optically tunable section 214 and, optionally, a thermo-optically tunable section 216. At the end opposite to the partial reflector 210, the laser cavity is bounded by a 1×2 optical coupler 218 that splits the light coming from the laser cavity between two coupling waveguides 220, 222, which are, in turn, coupled via two respective 2×2 directional optical couplers 224, 226 to ring waveguides implementing the two ring resonators 206, 208. (A 2×2 optical coupler is herein understood simply as a coupler with two inputs and two outputs; the term is not intended to imply 50% coupling.) At each of these ring-side 2×2 optical couplers 224, 226, a portion of the light coming from the cavity-side 1×2 optical coupler 218 is coupled at a first output port of the optical coupler 224, 226 into the respective ring resonator 206 or 208; the remaining portion is coupled at a second outport of the optical coupler 224, 226 into a respective waveguide termination, where it is dissipated.

As depicted, light coupled from the first coupling waveguide 220 into the first ring resonator 206 propagates counterclockwise in the first ring resonator 206, and light coupled from the second coupling waveguide 222 into the second ring resonator 208 propagates clockwise in the second ring resonator 208. The ring resonators 206, 208 are further coupled, by an additional 2×2 optical coupler 228, 230 in each of the ring resonators 206, 208, to a shared third coupling waveguide 232. Light propagating along the shared coupling waveguide 232 from one of the couplers 228, 230 to the other will in part be coupled at a first output port of the latter coupler 230, 228 into the associated ring resonator 208, 206, and in part be dissipated at a waveguide termination connected to the second port of the coupler 230, 228. As indicated by solid arrows in FIG. 2B, the counterclockwise propagating light in the first ring resonator 206 can couple at optical coupler 228 into the shared coupling waveguide 232, and from there at optical coupler 230 into the second resonator 208, where the light propagates counterclockwise until it couples back into the second coupling waveguide 222, and from there via the cavity-side optical coupler 218 into the cavity waveguide 212. Similarly, as indicated by dashed arrows, the clockwise propagating light in the second ring resonator 208 can couple at optical coupler 230 into the shared coupling waveguide 232, and from there at optical coupler 228 into the first ring resonator 206, where the light propagates clockwise until it couples, via optical coupler 224, back into the first coupling waveguide 220, and from there via the cavity-side optical coupler 218 into the cavity waveguide 212. Thus, a portion of the light coupled into either resonator 206, 208 is in effect reflected back into the laser cavity. The remaining portion of the light makes up the losses of the pair of ring resonators 206, 208, which largely result from dissipation at the waveguide terminations at the second output port of the 2×2 optical couplers 224, 226, 228, 230.

The amount of light that is transmitted through the ring resonators 206, 208, and thus ultimately reflected back into the cavity, is a function of the wavelength of the light, and is maximized at the resonances of the ring resonators 206, 208. The resonances, or transmission peaks, occur where the optical path length of one roundtrip along the ring, i.e., the circumference of the ring multiplied by its refractive index, is equal to an integer multiple of the wavelength, forming spectrum periodic in optical frequency, with transmission peaks spaced at the FSR of the ring resonator. As explained with reference to FIG. 1C, the ring resonators 206, 208 may be designed with slightly different FSRs to achieve a larger effective FSR that leaves a single cavity mode within the gain spectrum of the laser to be transmitted through the ring resonators and reflected back into the cavity. Each of the ring resonators 206, 208 is equipped with phase tuners 234, 236, 238, 240 that allow changing the refractive index along a section of the ring waveguides, thereby tuning the resonance frequency. Thermo-optic tuners 234, 236, e.g., implemented by heaters of variable power placed in the vicinity of the ring waveguides, can be used to slowly adjust the resonance frequencies to align the filter transmission maximum with a desired cavity mode and maintain the alignment, e.g., as the temperature changes. Electro-optic tuners 238, 240, e.g., implemented as diode structures created in the ring waveguides, can be used to vary the resonance frequency at a high speed, which allows tuning the filter transmission maximum along with the cavity mode to maintain alignment during frequency chirps of the laser.

The ring resonator configuration depicted in FIG. 2B is one among multiple options of implementing a wavelength filter with two ring resonators exploiting the Vernier effect. FIGS. 2C and 2D are structural schematics of alternative example tunable lasers 250, 260 with tunable ring-resonator-based optical filters, in accordance with various embodiments.

In the laser 250 of FIG. 2C, the two ring resonators 206, 208 are not configured in a loop that can be traversed in both directions, with a cavity-side 1×2 optical coupler 218 splitting light between paths to the two ring resonators 206, 208 and recombining the returned light, as shown in FIG. 2B. Rather, in FIG. 2C, the light coming from the laser cavity is partially coupled into only one of the ring resonators, 206, and from there via the shared coupling waveguide 232 partially into the other ring resonator, 208. A portion of the light propagating in the second ring resonator 208 is, at 2×2 optical coupler 226, coupled out of the ring resonator 208 and reflected at an optical reflector 252 (which has no equivalent in FIG. 2B). The reflected light is in part coupled via the optical coupler 226 back into the second ring resonator 208, from there via the shared coupling waveguide 232 back into the first ring resonator 206, and eventually back into the laser cavity. If the light coming from the laser cavity traverses the ring resonators 206, 208 in the counterclockwise direction, as is the case in FIG. 2C, the reflected light traverses the ring resonators 206, 208 in the counterclockwise direction, and vice versa.

In the laser 260 of FIG. 2D, the two ring resonators 206, 208 are placed on opposite ends of the laser cavity. On one end, light couples via a 2×2 optical coupler 224 into the first ring resonator 206 and via a 2×2 optical coupler 228 out of the ring resonator 206 into an associated output waveguide 262 at whose end the light is reflected by a reflector 264, and part of the reflected light traverses the output waveguide 262 and first ring resonator 206 to be coupled back into the laser cavity. At the other end, light couples via a 2×2 optical coupler 226 into the second ring resonator 208 and via another 2×2 optical coupler 230 out of the ring resonator 208 into an associated output waveguide 266 at whose end the light is partially reflected by a partial reflector 268, and partially transmitted to create the laser output. The reflected portion travels back through the output waveguide 266 and the second ring resonator 208 into the laser cavity. Alternatively laser configurations with two optical ring resonators may occur to those of ordinary skill in the art.

FIG. 3 is a top view of an example photonic circuit layout 300 of the tunable laser 200 with tunable ring-resonator-based optical filters of FIGS. 2A and 2B. In this layout 300, the partial reflector 210 is implemented by a waveguide loop reflector 302. The waveguide loop reflector 302 includes or consists of a waveguide section, contiguous with the cavity waveguide 212, that curves around to create a directional coupler between first and second portions at opposite ends of the waveguide section. Light that has traveled around the loop from the first portion to the second portion is partially transmitted to an optical output 304 of the laser, and partially coupled back into the first portion, now propagating in the reverse direction in the cavity waveguide 212. At the other end of the cavity waveguide 212, a multimode interferometer implementing the cavity-side optical coupler 218 splits the light between the first and second coupling waveguides 220, 222, which partially couple the light into the ring resonators 206, 208. As depicted, the ring resonators in this layout 300 are racetrack-shaped, with straight waveguide sections constituting a significant portion of the overall resonator round-trip length. The thermo-optic and electro-optic phase tuners 234, 236, 238, 240 extend along these straight sections, and likewise amount in length to significant portions of the resonator length (and thereby modify the refractive index over a substantial fraction of the resonator), as is important for efficient resonance tuning. The cavity waveguide 212, waveguide loop reflector 302, ring resonators 206, 208, and the first, second, and shared third coupling waveguides 220, 222, 232 are all silicon waveguide structures patterned in the silicon device layer of a substrate.

The thermo-optic phase tuners 234, 236 include heater metal structures 306, e.g., in the form of a winding or straight filament, above straight silicon waveguide sections of the ring resonators 206, 208. Each heater metal structure 306 is connected by electrical (e.g., metal) connections 307 between a pair of associated electrical terminals 308 that facilitate running an electrical current through the heater metal. If the cavity includes a thermo-optic phase tuner (not shown in FIG. 3), it can be similarly implemented.

The electro-optic phase tuners 238, 240 in the ring resonators 206, 208, as well as the electro-optic phase tuner 214 in the laser cavity, each include a vertical p-n or p-i-n diode structure 310 formed in III-V material disposed above the silicon device layer in respective waveguide sections of the ring resonators 206, 208 and cavity waveguide 212. Each diode structure 310 is connected by electrodes and electrical (e.g., metal) connections 311 between an associated pair of p-side and n-side electrical terminals 312 that allow applying an electrical voltage across the diode structure 310. As shown, in the ring resonators 206, 208, the p-side and n-side terminals may be shared between both electro-optic phase tuners 238, 240, resulting in inherent synchronization of the voltage waveforms applied to the electro-optic phase tuners 238, 240.

The optical gain section 202 in the laser cavity is likewise implemented by a vertical p-n or p-i-n diode structure 316 formed in III-V material disposed above the silicon device layer, and connected by electrical (e.g., metal) connections 317 between an associated pair of p-side and n-side electrical terminals 318 that allow applying an electrical voltage across the diode structure 310. The III-V material, or stack of materials, used in the gain section 202 usually differs from the III-V material, or stack of materials, used for the electro-optic phase tuners 238, 240, 214, allowing the III-V material in the gain section to be optimized for amplification and the III-V material in the phase tuners to be optimized for efficient refractive-index modulation. The phase tuner 238, 240 in the ring resonator filters and the phase tuner 214 in the cavity may, but need not necessarily, use the same III-V material.

The III-V diode 316 implementing the gain section, although serving the purpose of amplifying light in the cavity, inevitably also imparts a phase shift due to a change in refractive index. The refractive index change has a linear relationship with carrier density, whereas the material gain has a nonlinear logarithmic relationship with carrier density. This difference can be exploited to, in effect, decouple the gain from the phase shift by implementing the gain section with two sub-sections with separate respective sets of electrodes that allow controlling the carrier density separately in each section. A given net gain achieved by operating both sections at the same carrier density can then alternatively be reached by operating one section at much higher and one section at slightly lower carrier density. For these two equivalent gain conditions, the second has higher refractive index change because the average carrier density is higher. Taking advantage of this effect, a pair of inverse modulation voltages can be applied to the two gain sections to chirp the laser frequency with minimal change to the laser output power. In some embodiments, therefore, in place of dedicated phase-tuning and gain sections 204, 202, two gain sections are used in conjunction to provide both the gain and the phase shift used for chirping the laser, for improved power and phase control

The III-V diode structures 310, 316 of the electro-optic phase tuners 214, 238, 240 and gain section 202 in the laser cavity and in the ring resonators are elongated III-V waveguide sections that form part of hybrid silicon/III-V waveguides. To better couple light from the silicon layer into the III-V layer in a region where the two overlap, the silicon waveguide may be tapered, decreasing in width in a direction towards the III-V waveguide sections and either continuing at decreased width or vanishing entirely underneath the III-V waveguide section. Alternatively or additionally, the III-V waveguide sections may be tapered in the overlap region, decreasing in width in a direction towards the silicon-only portion of the waveguides.

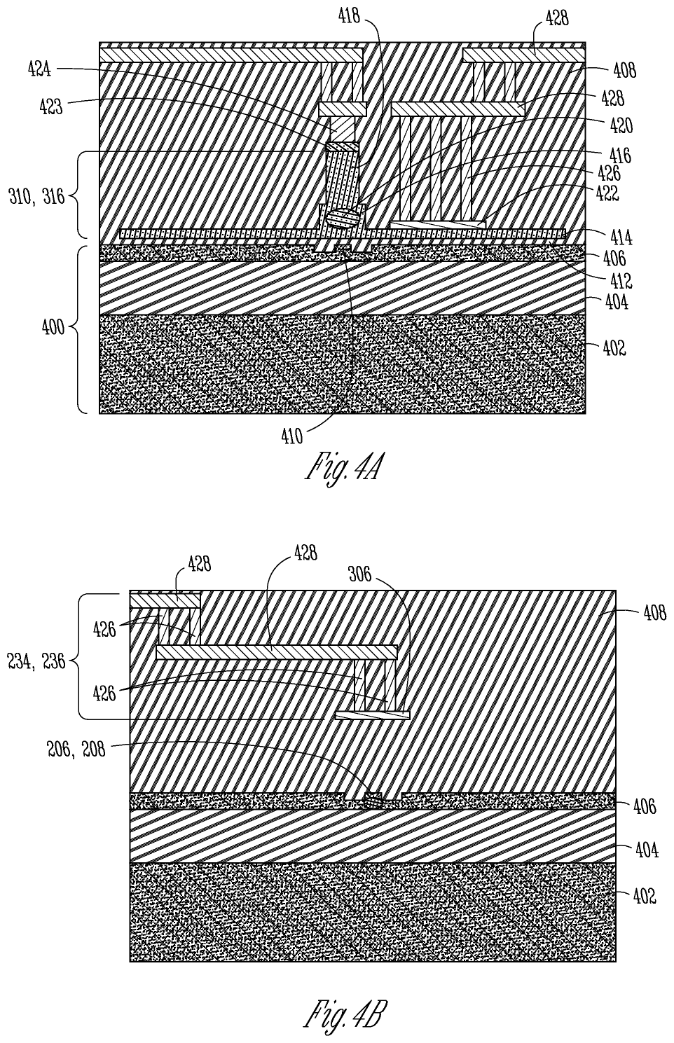

FIGS. 4A and 4B are schematic transverse cross sections of the tunable laser with tunable ring-resonator-based optical filters in the example layout 300 of FIG. 3 at locations of the III-V diode structures 310, 316 and thermo-optic phase tuners 234, 236, respectively. (A transverse cross section, as herein understood, shows the in-waveguide plane, that is, a cross-sectional plane perpendicular to the waveguide axis.) As can be seen in both figures, the laser is implemented on a silicon-on-insulator (SOI) wafer 400 that includes, on top of the silicon substrate 402, an insulting layer such as a silicon oxide or other buried oxide (Box) layer 404 and a silicon device layer 406. The silicon device layer 406 is patterned, e.g., by standard photolithographic patterning and etching processes, to form the various silicon waveguide structures. A top oxide cladding 408 encapsulates the III-V diode structures 310, 316 and heater metal structures 306 along with their associated electrodes and metal connections.

FIG. 4A is a schematic cross section of the III-V diode structure 310, 316 in any of the electro-optic phase tuners 214, 238, 240 or the gain section 202. The diode structure 310, 316 is centered above a silicon waveguide 410 formed between a pair of channels partially etched into the silicon device layer 406; this waveguide 410 may be the cavity waveguide 212 or either one of the ring waveguides implementing the ring resonators 206, 208. The diode structure 310, 316 is generally formed by patterning, e.g., using standard photolithographic patterning and etching processes, a III-V die including multiple vertically stacked layers, bonded either directly to the silicon device layer 406 or, as shown, to a thin oxide layer 412 covering the silicon device layer 406. The diode structure 310, 316 includes, as its bottom layer 414, a wide strip of doped material, and disposed on this bottom layer 414, a much narrower mesa structure including an intrinsic layer 416 and a doped top layer 418, the dopings of the top and bottom layers 414, 418 being of opposite types. Typically, the bottom layer 414 consists of n-type doped material and the top layer 418 of p-type doped material, but the reverse is also possible. In operation, the optical mode, indicated at 420, will be coupled into and propagate primarily in the intrinsic layer 416. N-contact metal 422 disposed on the n-type bottom layer 414 and p-contact metal 424 disposed directly on the p-type top layer 418 or on an intervening p-type doped III-V contact layer 423 form a pair of electrodes for applying an electrical voltage across and/or electrical current through the diode structure 310, 316 (with voltage control usually being preferred for the phase shifters and current control usually being preferred for the gain section). The n-contact metal 422 and p-contact metal 424 are electrically connected to respective electrical terminals 312, 318 by vertical metal vias 426 and metal traces in one or more metal routing layers 428.

FIG. 4B is a schematic cross section of a thermo-optic phase tuner 234, 236 above either of the ring resonators 206, 208. The thermo-optic phase tuner 234, 26 includes a heater metal structure 306 disposed, and typically centered, above the ring waveguide, which carries the optical mode in operation. Metal vias 426 and metal traces in one or more metal routing layers 428 provide the electrical connections for applying an electrical current to heat up the heater metal structure 306. Usually, the metal connections to the two terminals are placed, in a direction along the ring waveguide, on opposite sides of the heater metal structure 306.

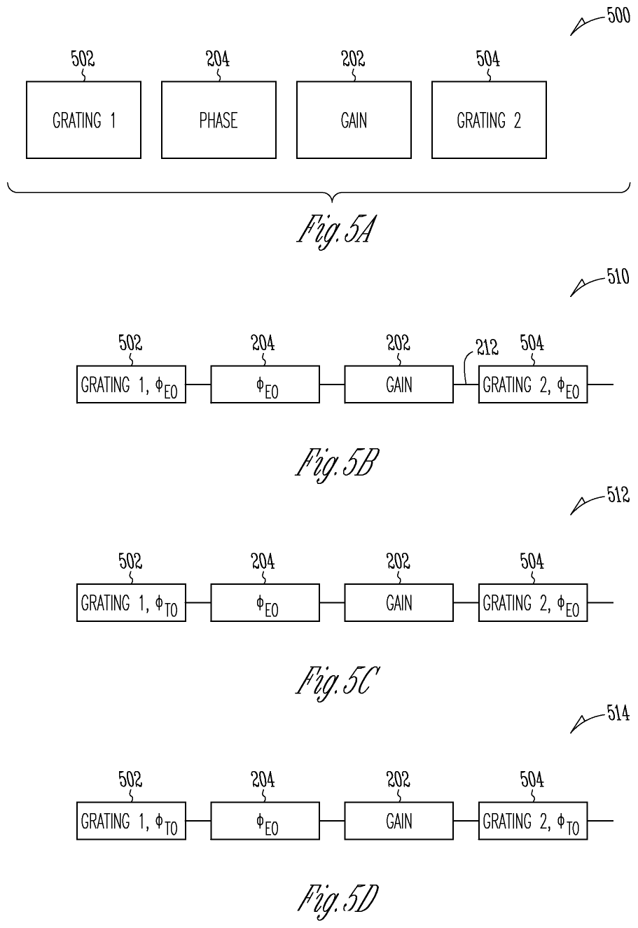

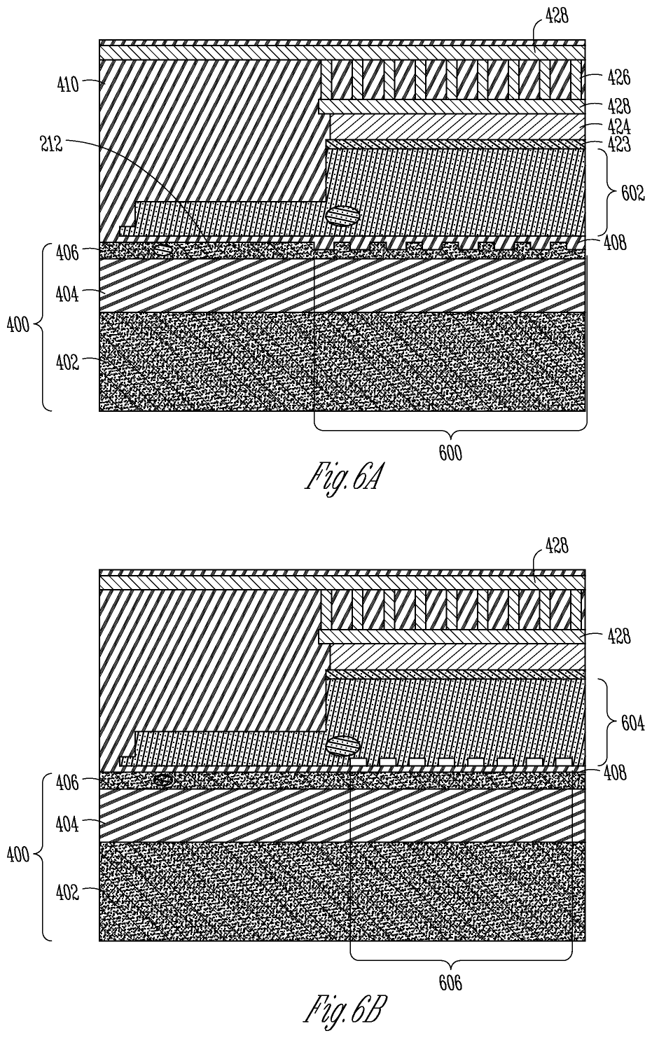

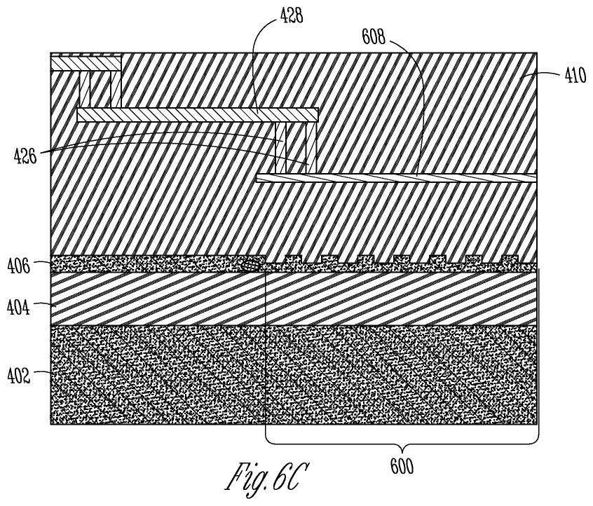

FIG. 5A is a conceptual block diagram of an example tunable laser 500 with grating-based optical filters, in accordance with various embodiments. The tunable laser 500 includes an optical gain section 202 and a phase-tuning section 204 placed between a pair of optical gratings 502, 504 that define the boundaries of the laser cavity and, together with the laser cavity, form the laser resonator. One or both of the gratings 502, 504 also constitute wavelength filters to select a single cavity mode for lasing. The gratings 502, 504 are only partially reflective, and light transmitted through the gratings makes up the major portion of the optical losses of the wavelength filters and the resonator as a whole. Either of the gratings 502, 504 may serve as the laser output. In some embodiments, light output through both gratings is combined to maximize the laser output power.

FIGS. 5B-5D are structural schematics of example lasers 510, 512, 514 constituting various embodiments of the example tunable laser 500 of FIG. 5A. As shown, the gain section 202, phase-tuning section 204, and gratings 502, 504 are formed along a cavity waveguide 212. The phase-tuning section 204 includes an electro-optically tunable section (as shown) and, optionally, a thermo-optically tunable section (not shown). Alternatively, as explained above in the context of FIG. 3, the phase-tuning and gain sections 204, 202 may be replaced by two gain section operated to provide both optical gain and a tunable phase shift in the cavity.

In the example laser 510, the gratings 502, 504 are both narrow-band gratings configured to select a single cavity mode for lasing, and each grating is equipped with at least an electro-optic phase tuner, as shown in FIG. 5B, and optionally additionally with a thermo-optic phase tuner. The phase tuners are configured and driven to select the same cavity mode with both gratings. In operation, synchronized high-speed waveforms are applied to the electro-optic phase tuners in both gratings 502, 504 and in the intra-cavity phase-tuning section 204, allowing for a large chirp amplitude. The thermo-optic tuners, if present, may be used for low-speed adjustments, e.g., responsive to temperature fluctuations.

In the example laser 512 shown in FIG. 5C, only one of the gratings (as depicted, grating 504) is a narrow-band grating configured to select a single cavity mode, equipped with an electro-optic phase tuner. The other grating (as depicted, grating 502) is a wide-band grating that reflects multiple cavity modes. The wide-band grating may include a thermo-optic phase tuner to facilitate slow shifts of its reflection spectrum, and is generally configured such that its reflection spectrum overlaps with that of the narrow-band grating. In operation of the laser 512, the electro-optic phase tuners in the narrow-band grating and in the phase-tuning section 204 of the laser cavity are driven in accordance with high-speed synchronized waveforms. The laser 512 can achieve the same large chirp amplitude as the laser 510, but due the use of a broad grating, it does not achieve the same narrow linewidth. In various modifications of laser 512, the wide-band grating can be replaced by another wide-band optical reflector, such as, e.g., a waveguide loop reflector.

In the example laser 514 shown in FIG. 5D, both gratings 502, 504 are narrow-band gratings configured to select a single cavity mode, equipped with thermo-optic phase tuners, but not electro-optic phase tuners. In this embodiment, the laser 514 has a good optical linewidth, but the laser frequency can be chirped only over the width of the reflection spectrum of the gratings 502, 504 before a mode hop occurs. The thermo-optic phase tuners are used to set the center wavelength of the filter reflection spectrum, corresponding to the selected cavity mode, and to maintain mode-hop free performance over temperature.

FIGS. 6A-6C are schematic longitudinal cross sections of the example tunable lasers 500, 510, 512, 514 with grating-based optical filters of FIGS. 5A-5D, taken along the length of the cavity waveguide at locations of electro-optic and thermo-optic phase tuners. (A longitudinal cross section, as herein understood, shows the across-waveguide plane, that is, a cross-sectional plane parallel to the waveguide axis and perpendicular to the plane of the substrate.) In each case, like in the lasers with ring-resonator-based filters described with reference to FIGs. 2A-4B, the laser is implemented on an SOI wafer 400 that includes a silicon substrate 402, an insulting layer such as a silicon oxide or other Box layer 404 and a silicon device layer 406, and a top oxide cladding 408 encapsulates III-V diode structures and heater structures implementing the electro-optic and thermo-optic phase tuners.

FIG. 6A shows a portion along the laser that encompasses part of the laser cavity (on the left) and part of a grating 600 defining the boundary of the cavity and an associated electro-optic phase tuner (on the right). The grating 600 is, in this embodiment, formed in the cavity waveguide 212 by a periodic partial etch of the silicon layer, e.g., down to the depth of the pair of longitudinal channels that define the waveguide therebetween, or some other depth (usually the latter). The amount of light that is reflected at the grating 600 is a function of the wavelength of the light, and peaks where the grating period is equal to half the wavelength. A III-V diode structure 602 including a doped bottom layer, intrinsic layer, and doped top layer (e.g., with n-type doping in the bottom layer and p-type doping in the top layer, or vice versa) is formed above the grating 600 and a preceding portion of the cavity waveguide 212, optionally separated from the silicon device layer 406 by a thin oxide layer 412. The III-V diode structure 602 has associated electrodes (implemented by n-contact metal disposed on the n-type bottom layer and p-contact metal 424 disposed directly on the p-type top layer or on an intervening p-type doped III-V contact layer 423) along with electrical connections (implemented by metal vias 426 and metal trances in one or more metal routing layers 428) to respective n and p terminals for applying an electrical voltage across the diode structure 604. In operation, the optical mode is coupled from the silicon layer into the intrinsic layer of the diode structure, where the applied voltage induces a variable refractive-index change, corresponding to a change in the local wavelength of the light at any given frequency. The optical mode has a small overlap with the grating 600 in the silicon device layer 406, which results in optical coupling with the grating 600 with a low grating coupling coefficient, and provides a narrow mirror reflectivity spectrum peaking at a frequency that shifts with the voltage applied to the III-V diode structure 602. The longer the III-V diode structure 602 and grating 600 are, the stronger is the reflection from the grating 600. However, the optical losses added by the III-V diode structure 602 due to scattering and absorption limits the maximum possible grating length.

FIG. 6B shows an alternative embodiment of a grating with an associated electro-optic phase tuner. Here, the grating is implemented in the III-V layer rather than the silicon layer. Specifically, as shown, a diode structure 604 disposed above the cavity waveguide 212, otherwise similar to the diode structure 602 of FIG. 6A, is patterned at the bottom to form a periodic grating 606. In operation, the optical mode coupled into the diode structure 604 is reflected at that grating 606, whose reflection spectrum can be shifted electro-optically in frequency, due to a change in refractive index and local wavelength at given frequency, by application of a voltage across the diode structure 602 via associated electrodes. The grating 606 can be created in the III-V die by electron beam or nano-imprint lithographic patterning and standard etching processes, prior to flip-chip bonding the III-V die to the patterned SOI wafer 400.

FIG. 6C shows a portion along the laser that encompasses part of the laser cavity (on the left) and part of a grating 600 and an associated thermo-optic phase tuner (on the right). Here, like in FIG. 6A, the grating 600 is created in the cavity waveguide 212 by a periodic partial etch of the silicon device layer 406. Above the grating 600, a heater metal structure (e.g., metal filament) 608 is disposed. In operation, an electrical current applied through the heater metal structure 608 via associated electrical connections (implemented by metal vias 426 and metal traces in one or more metal routing layers 428) heats the heater metal structure 608 and thereby the nearby grating 600, effecting a thermo-optically induced refractive-index change and corresponding phase shift to frequency-tune the reflection spectrum of the grating 600.

The choice of phase tuners employed in the chirped laser (e.g., laser 200 or 500) laser generally present a trade-off between different characteristics, and different phase tuners are therefore used for different purposes. Thermo-optic tuners are beneficial in that they can achieve a large refractive index change and do not incur changes in optical losses incidental to refractive-index changes, allowing the wavelength of the laser to be adjusted without affecting cavity losses. Therefore, thermo-optic tuners are commonly used to compensate for large changes in ambient operating temperature, enabling uncooled operation of the laser. However, due to the slow thermal effects underlying their operation, thermo-optic tuners are limited in the modulation frequencies (that is, the number of chirp cycles per second) they can achieve, typically to less than 100 kHz, whereas electro-optic tuners can work at modulation frequencies up to 100 GHz. Therefore, chirped lasers as described herein utilize electro-optic phase tuners in the laser cavity, and unless a chirp range within the width of the filter spectrum is sufficient, also in the wavelength filters.

The electro-optic phase tuners in the cavity or the wavelength filters may be implemented in the III-V (or other compound semiconductor) layer (as illustrated in FIGS. 4A-4B and 6A-6B) as forward-biased or reverse-biased p-n or p-i-n junctions, or in the silicon layer as forward-biased or reverse-biased p-n junctions. The physical effect relied upon to achieve the phase shift depends on a combination of the material properties and the direction and magnitude of the bias voltage, and generally determines the achievable tuner chirp range and optical losses introduced incidentally to phase tuning. The direction of the bias voltage generally effects the phase change per unit length and unit volume, hereinafter the “specific tuning efficiency” (to distinguish it from the tuning efficiency of the phase tuner at large), and the tuning speed.

Forward-biased tuners, whether implemented in silicon or III-V material, are dominated by the free-carrier absorption effect. With free carrier absorption, the optical loss in the waveguide changed by increasing the carrier density, and this change in absorption causes a change in refractive index and a concomitant change in the net phase shift through the tuning section. Forward-biased tuners can achieve chirp ranges up to about 50 GHz, limited by the optical loss and reduction in laser output power during the chirp. They tend to be more efficient than the reverse-biased tuners, achieving comparable chirp amplitudes at lower swing voltages (e.g., 50 GHz at less than 1 V peak to peak), but modulate the frequency at lower speed due to the slower current injection.

Reverse-biased silicon tuners are dominated by the free carrier concentration in the waveguide and work similar to forward-biased silicon tuners, but at faster speeds due to faster carrier transport, and with lower efficiency due to a smaller tuning effect in reverse bias. These tuners can achieve chirp ranges up to about 50 GHz, limited by the reduction in laser output power during the chirp. To make up for the smaller phase shift per unit length, reverse-biased silicon tuners are typically longer than forward-biased silicon tuners (e.g., 4000 μm, as compared with 100 μm).

Reverse-biased III-V-based tuners are usually dominated by the linear electro-optic effect at low bias voltages with low carrier concentrations around the waveguide and a bandgap wavelength of the waveguide material far lower than the operating wavelength, which reduces absorption effects. With the linear electro-optic effect, the electric field generated in the waveguide material due to application of a voltage at the electrodes causes a change in the refractive index, and therefore a change in the net phase shift through the tuning section. Tuners operating based on the linear electro-optic effect incur negligible optical losses, but are limited to maximum chirp ranges of only about 10 GHz, as determined by the maximum refractive index change and reverse bias breakdown voltage of the material. Additionally, due to lower specific tuning efficiency, they are roughly twenty-five times longer (e.g., 4 mm) than forward-biased phase tuners for the same tuning range and use large swing voltages (e.g., up to 10 V peak to peak). However, they can modulate the frequency at higher speed due to the faster electric field changes, and provide good chirp linearity.

Reverse-biased III-V tuners driven at high bias voltages are usually dominated by the quadratic electro-optic effect or quantum-confined Stark effect (if quantum wells are used in the III-V material). With these effects, the optical loss in the waveguide is changed by the electric field applied across the waveguide material due to application of a voltage, and the change in absorption causes a change in refractive index, and therefore a change in the net phase shift through the tuning section. Phase tuners operating based on the quadratic electro-optic effect experience only about half the optical losses for a given refractive index change as are incurred using free-carrier absorption, and accordingly can achieve chirp ranges of up to 100 GHz as limited by the reduction in output power. Further, they allow for fast tuning due to the fast electric field changes. However, due to lower specific tuning efficiency, reverse-biased III-V-based tuners are approximately three times longer than forward-biased phase tuners for the same phase tuning range and use large swing voltages (e.g., up to 10 V peak to peak).

Comparing these electro-optic tuner options for application to Lidar lasers, forward-biased tuners are capable of fine depth resolution scanning due to their large achievable chirp range, and preferrable for system integration due to their low modulation voltage requirements. Reverse-biased tuners utilizing the linear electro-optic effect are preferrable for long range detection with coarse depth resolution scanning, due to their highly linear chirp and small chirp range.

FIG. 7 is a graph illustrating the simulated laser output power 700 as a function of wavelength shift for a chirped laser in accordance with one example embodiment. The simulation was performed for a laser with ring-resonator-based wavelength filters and electro-optic intra-cavity and filter phase tuners implemented by silicon p-n junctions operating in forward bias via free-carrier absorption; similar performance is expected for III-V p-n junctions operating via free-carrier absorption. For purposes of the simulation, it has been assumed that the wavelength filters and cavity mode have been aligned with each other using thermo-optic tuners, and that the tuning efficiencies of the intra-cavity and filter phase tuners have been calibrated to maintain equal tuning rates during the chirp. Prior to application of a voltage on the electro-optic phase tuners, the laser output power is 20 mW. As an increasing forward voltage is applied to the electro-optic phase tuners, the refractive index decreases, and therefore the laser wavelength decreases, and the laser frequency increases correspondingly. The increase in laser frequency is accompanied by a drop in laser output power, which is roughly linear, until it falls below 1 mW, where the laser becomes unstable and eventually stops lasing due to losses in excess of the amplification in the gain section. This point 702 constitutes the tuning limit of the laser, and occurs in this example at a maximum wavelength shift of about −0.3 nm, or equivalently a frequency shift of +55 GHz. The drop in laser power that results from losses incidental to phase tuning affects, in turn, the refractive index in the gain section, contributing to the overall phase shift incurred in the laser cavity and thus reducing the tuning required on the intra-cavity phase tuner to maintain alignment with the wavelength filters, in some cases by more than 10%. This effect can be accounted for by performing a fine calibration of the tuning rates of the electro-optic phase tuners once a chirp of the desired magnitude has been applied.

Due to the change in optical losses that occur as the laser is chirped in frequency, the laser output power generally varies during the chirp. One option to compensate for this variation and stabilize the output power is to modulate the laser gain via the gain current during the chirp. In view of the interdependence between laser gain and phase shift in the cavity, however, it may be simpler and hence preferable to leave the gain current constant and instead apply a variable amplification of the light that is output by the laser (which presumes, of course, that the gain current remains above the varying lasing threshold throughout the chirp). For this purpose, chirped laser systems in accordance with various embodiments include a semiconductor optical amplifier (SOA) after the output of the laser. The SOA is driven in synchronization with the electro-optic phase tuners

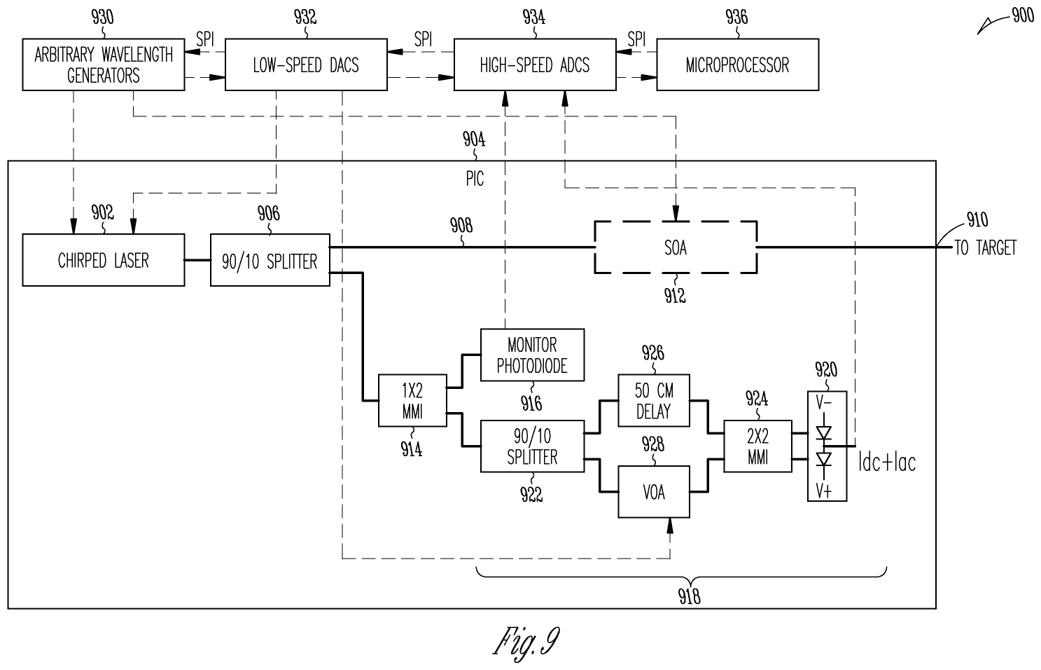

FIGS. 8A and 8B are graphs conceptually showing waveforms of the laser output power before and after amplification in accordance with one example embodiment. As shown in FIG. 8A, the output power of the laser may vary in an approximately triangular fashion, going down and back up during each chirp cycle (i.e., as the frequency is tuned up and down). To at least partially compensate for this variation, an SOA at the laser output can be driven with a drive current that has an increasing slope when the laser output power has a decreasing slope. After such amplification, as shown in FIG. 8B, the variation in laser output power is substantially reduced.

Having described various structural implementations of chirped lasers and associated performance characteristics, the discussion will now turn to systems and methods of calibration and controlling such lasers.

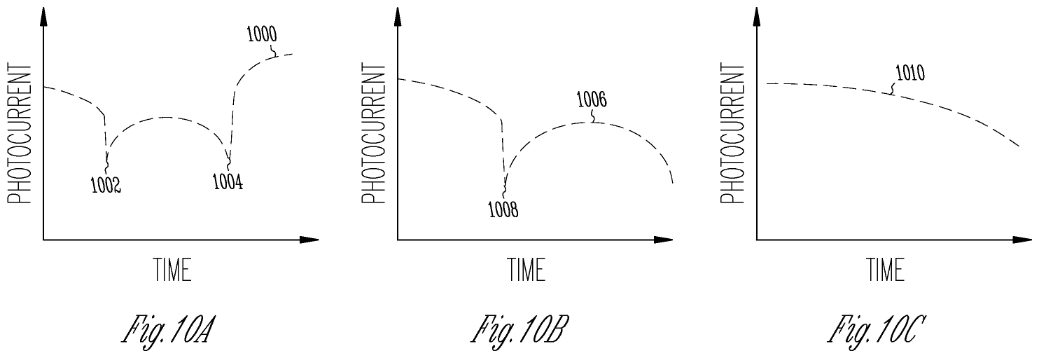

FIG. 9 is a block diagram of an example chirped laser system 900 in accordance with various embodiments. The system 900 includes a number of photonic and electronic circuit components that collectively facilitate monitoring and controlling the chirped laser 902. The photonic circuit components are integrated along with the laser 902 itself on a single chip as a photonic integrated circuit (PIC) 904. The electronic circuit components may be implemented on one or more separate chips. The PIC 904 and electronic circuit chip(s) may be bonded, e.g., via solder bumps, to a common substrate, such as a printed circuit board that provides electrical connections between the electronically driven photonic circuit components and the respective electronic drivers. However, other ways of packaging the PIC and electronic chip(s) are also conceivable.

The PIC 904 includes, at the output of the chirped laser 902, an optical splitter 906 that branches off a portion of the output light into a monitoring circuit, and directs the majority of the light via an output path 908 to an output port 910, e.g., at a split ratio of 90/10. Light leaving the output port 910 is, in practical use, transmitted to a target. The laser light sent to the output port 910 may be amplified by an optional SOA 912 in the output path 908, as explained above with reference to FIGS. 8A-8B. In the monitoring circuit, a second optical splitter 914, e.g., implemented by a 1×2 multimode interferometer (MMI), divides the branched-off portion further between a monitor photodiode 916 and an interferometric wavelength monitor 918. The monitor photodiode 916 serves to measure the output power of the laser via the generated photocurrent. The interferometric wavelength monitor 918 is used to measure the chirp of the laser 902. In the depicted embodiment, the interferometric wavelength monitor 918 includes an asymmetric Mach-Zehnder interferometer (AMZI) with a balanced receiver 920 at its output. The AMZI is implemented by two waveguide arms (implementing two interferometer paths) coupled between a third optical splitter 922 at the input and a 2×2 optical combiner 924, e.g., implemented by a 2×2 MMI, at the output. The splitter 922 divides the light, generally unevenly (e.g., at a split ratio of 90/10), between the two waveguide arms. The first waveguide arm includes a delay element 926, such as a waveguide delay line of fixed length (e.g., 50 cm), to impart a phase shift relative to the second waveguide arm that depends on the wavelength of the light. Since the delay element 926 causes substantial optical losses, the first waveguide arm receives the greater fraction of the light from the optical splitter 922 to roughly balance out the optical power at the inputs to the combiner 924; fine adjustments can be made with a variable optical attenuator (VOA) 928. The VOA may be included in the second waveguide arm, as shown, or in the first waveguide arm if the split ratio between the waveguide arms is set to overcompensate for the losses in the delay element. The optical combiner 924 recombines the light from both interferometer paths, generating at its two output ports two complementary interference signals indicative of the phase difference between the paths. These interference signals can be measured by the balanced receiver 920. The balanced receiver 920 includes two photodetectors, one at each of the two outputs of the optical combiner 924, and is configured to output an electrical signal corresponding to the difference between the two respective photocurrents.

The electronic circuit components include one or more arbitrary waveform generators 930 to provide the high-speed drive signals for the electro-optic tuners in the cavity and filters of the chirped laser 902 and, if applicable, for the SOA 912. Further, the electronic circuit components include low-speed digital-to-analog converters (DACs) 932 to provide drive signals to the thermo-optic tuners and the gain section of the laser 902, as well as to the VOA 928 in the interferometric wavelength monitor 918. In addition to these electronic drivers 930, 932, the electronic circuit components include high-speed analog-to-digital converters (ADCs) 934 that convert the analog signals output by the monitor photodiode 916 and balanced receiver 920 of the PIC 904 into digital monitoring data, and a microprocessor 936 that processes the monitoring data to generate digital control data controlling the operation of the electronic drivers 930, 932. Data may be transmitted between the microprocessor 936 and the arbitrary waveform generator 930, low-speed DACs 932, and high-speed ADCs 934 via a serial peripheral interface (SPI) or similar low-power chip-to-chip control interface.

Chirping the frequency of the laser 902 generally involves tuning the electro-optic intra-cavity phase tuner and the electro-optic filter phase tuner(s) in synchronization and at the same frequency tuning rate, that is, the same frequency shift per unit time (e.g., measured in GHz/μs). The frequency tuning rate is the product of the tuning efficiency measured in frequency shift per change in the applied voltage (e.g., GHz/mV) and the voltage tuning rate (e.g., measured in mV/μs). Accordingly, equal frequency tuning rates are achieved if the ratio of the voltage tuning rates applied to the electro-optic intra-cavity and filter phase tuners—which translates for synchronous voltage waveforms to the ratio of the waveform amplitudes—is the inverse of the respective tuning efficiencies of the phase tuners. The tuning efficiencies, however, are generally not known a priori, at least not precisely, and are therefore to be calibrated. In accordance with various embodiments, this calibration is performed by tuning the intra-cavity phase tuner and measuring its tuning efficiency while the filter phase tuners are held constant, and vice versa. During such tuning of one phase tuner relative to the other(s), the cavity modes move past the filter spectrum, causing variations in the optical output power, including abrupt changes where mode hops occur, which can be measured with the monitor photodiode 916. Accordingly, the tuning efficiencies can be measured in terms of the number of mode hops occurring over a certain voltage range. The laser can then be chirped mode-hop-free by setting the relative amplitudes of the waveforms with which the electro-optic tuners in the cavity and the wavelength filters are driven to the inverse of the calibrated tuning efficiencies. Alternatively to measuring the tuning efficiencies explicitly, they can be calibrated implicitly by iteratively adjusting the amplitude ratio of the voltage waveforms applied to the intra-cavity and filter phase tuners until any mode hops have been eliminated from the photocurrent. Either way, once the laser is chirped mode-hop-free, a fine calibration can be performed to further improve photocurrent uniformity across the chirp. For example, the voltage waveform amplitudes for the intra-cavity phase tuner and filter phase tuners may be successively varied by +/−10% (or some other small value) and the corresponding time-dependent photocurrent measured to determine whether small changes in amplitude improve uniformity.

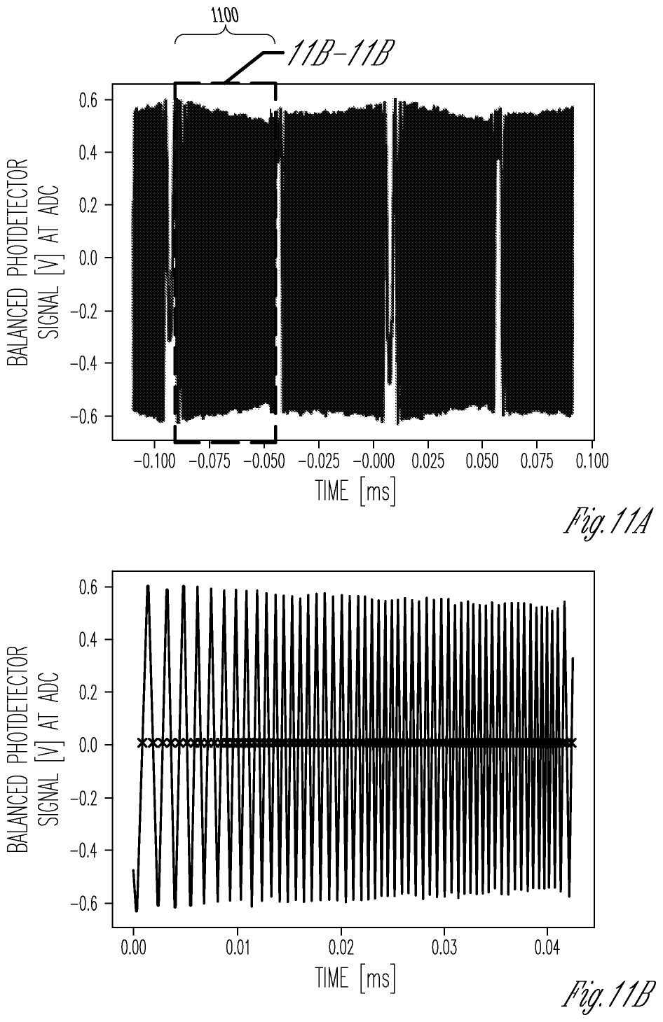

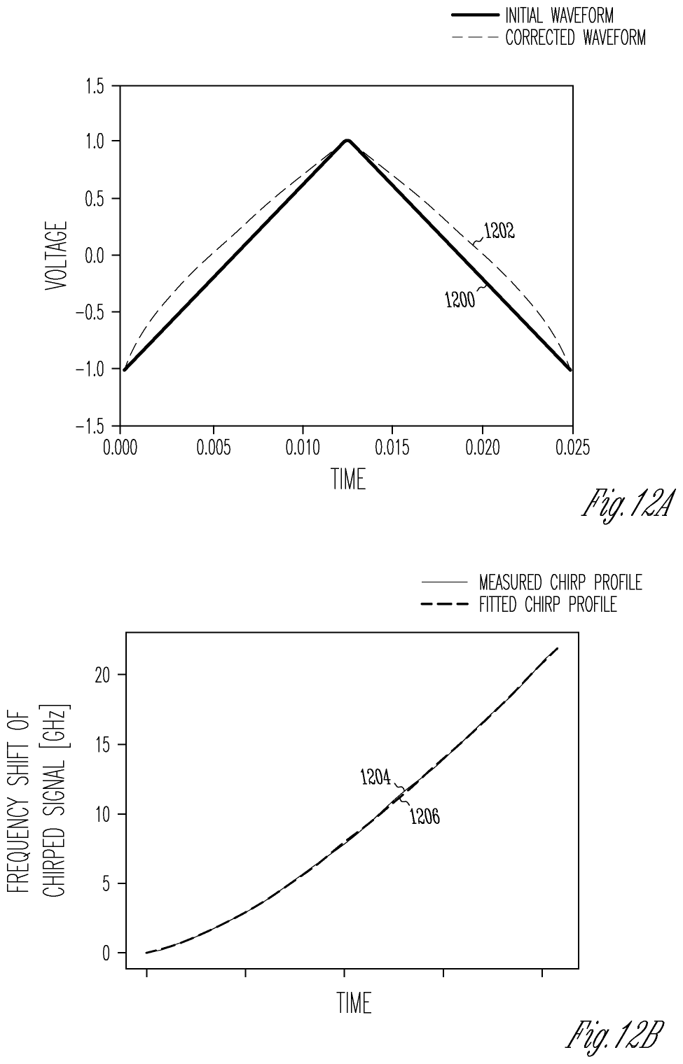

FIGS. 10A-10C are graphs illustrating the calibration of electro-optic tuners in the chirped laser based on negative spikes in laser output power during a chirp, in accordance with various embodiments. The figures each show a photocurrent indicative of the laser output power, e.g., as measured by the monitor photodiode 916, as a function of time during one full chirp. In FIG. 10A, the time-dependent photocurrent 1000 exhibits two sharp negative spikes 1002, 1004, corresponding to abrupt reversals in the slope of the photocurrent, which result from mode hops. These mode hopes are a consequence of significantly different frequency tuning rates between the intra-cavity phase tuner and the filter phase tuner(s). In FIG. 10B, the imbalance has been partially corrected, that is, the voltage tuning rates of one (or both) of the intra-cavity phase tuner and the filter phase tuner(s) have been adjusted to decrease the difference in frequency tuning rates. As a result, the photocurrent 1006 undergoes only one negative spike 1008 during the chirp. In FIG. 10C, the imbalance has been fully corrected, and the intra-cavity and filter phase tuners now apply chirps of the same magnitude and at the same rate, such that the selected cavity mode and filter spectrum remain aligned and the photocurrent 1010 is free of mode hops throughout the full chirp. The droop in the photocurrent 1010 over time is due to increased optical losses as the electro-optic tuners are operated.

Once the tuning efficiencies of the intra-cavity and filter phase tuners have been calibrated (explicitly or implicitly) and the intra-cavity and filter phase tuners are driven at relative voltage waveform amplitudes that achieve mode-hop-free operation, the chirp is measured and the absolute values of the tuning efficiencies are scaled (that is, adjusted by the same factor) to achieve the desired target chirp amplitude. Since the chirp amplitude affects the losses incurred in the wavelength filters, and the losses in turn affect the phase shift imparted in the gain section, which can cause a slight drift in frequency between the previously calibrated phase tuners, a fine calibration of the relative voltage waveform amplitudes may be performed once the target chirp amplitude has been reached. Further, measurements of the frequency as a function of time during the chirp may be used to ascertain the degree of chirp linearity, and predistort the voltage waveforms to correct for any nonlinearity.

The chirp measurements can be performed with the interferometric wavelength monitor 918, whose output signal is periodic in the laser frequency. In more detail, the photocurrents measured at the outputs of the optical combiner 924 of the AMZI, and thus also the balanced photocurrent measured with the balanced receiver 920, vary sinusoidally with the phase difference between the optical signals from the two interferometer paths that interfere at the optical combiner 924. That phase difference Δϕ is proportional to the instantaneous laser frequency ƒ: Δϕ=2π·n_{g}L/c·ƒ, where c is the speed of light in vacuum and L and n_{g} are the length and group refractive index of the delay element 926, respectively. Accordingly, one period of the photocurrent corresponds to a frequency shift of Δƒ=c/(n_{g}L), herein also called the “AMZI frequency.” The cumulative frequency shift incurred by the laser as a function of time can, thus, be determined from the cumulative periods of the measured photocurrents. In principle, the periods of the photocurrent can be determined from the photocurrent measured at either one of the two outputs of the optical combiner 924, but the balanced photocurrent output by a balanced receiver 920 as shown in FIG. 9 is beneficial in that it provides twice the signal amplitude and allows the periods to be conveniently determined based on a count of the zero crossings of the signal (which occur twice per period).

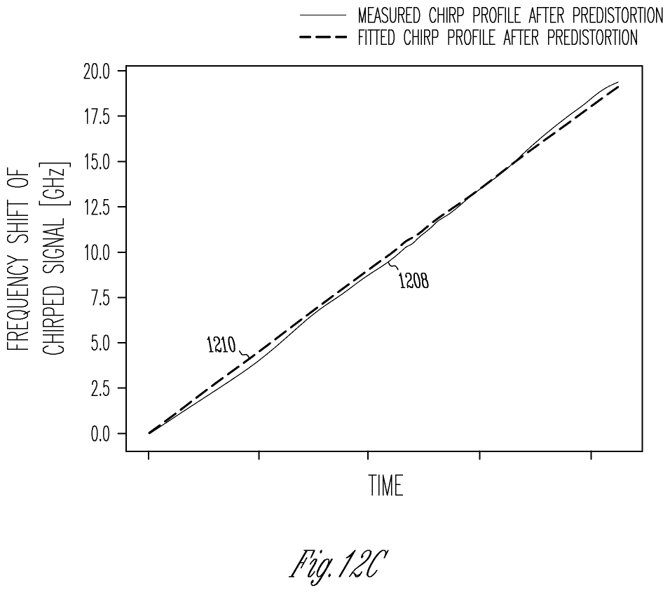

FIGS. 11A and 11B are graphs illustrating measurements of laser chirp via a balanced photocurrent at the output of an interferometric wavelength monitor, in accordance with various embodiments. FIG. 11A shows the balanced photodetector signal (e.g., measured in Volts at an ADC 934 connected to the balanced receiver 920) as a function of time (e.g., in milliseconds) over multiple chirp periods (each chirp period corresponding to half a waveform, that is, a monotonous chirp in one direction). This signal may be processed in the microprocessor 936. Processing may involve truncating the signal to keep only a single chirp period 1100, and removing a specified fraction at the beginning and end of the period where the chirp direction changes from positive to negative and the signal quality is poor. In the resulting truncated signal, which is shown in FIG. 11B, all zero crossings (indicated by “x”) are determined. Duplicate zero crossings may be removed to retain only a single zero crossing per measured oscillation cycle of the signal. The cumulative number of zero crossings as a function of time is multiplied by the AMZI frequency to calculate the cumulative frequency shift versus time. For most practical applications, the chirp is preferably linear. However, application of a triangular voltage waveform, where the voltage increases or decreases linearly in each segment, does generally result in a slightly nonlinear chirp. This is illustrated in FIG. 11B by the decreasing period of the balanced photodetector signal over time as the applied voltage increases, corresponding to an increasing chirp rate. To linearize the chirp, the voltage waveform may be predistorted.

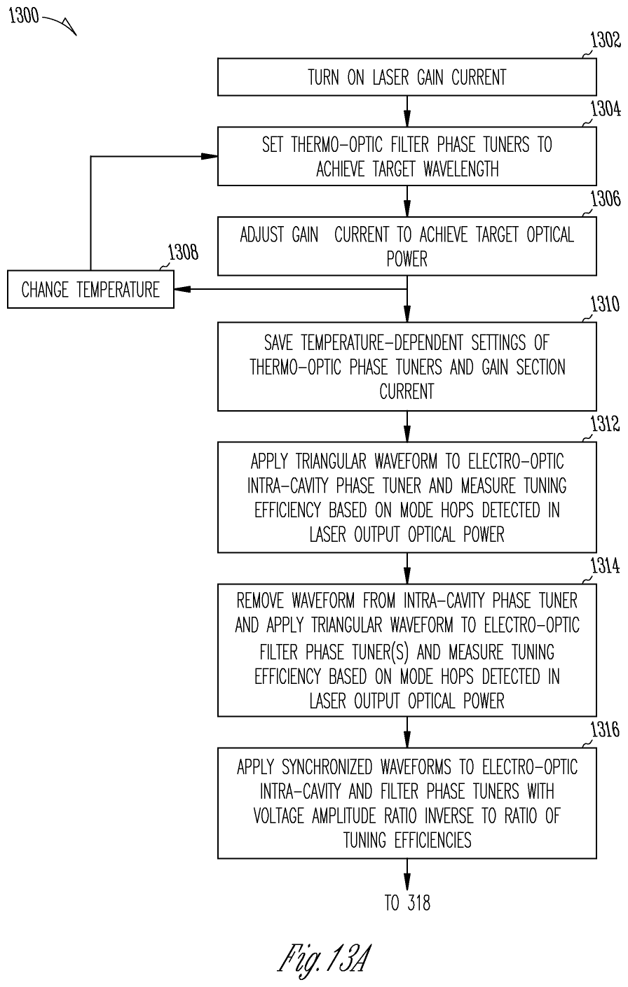

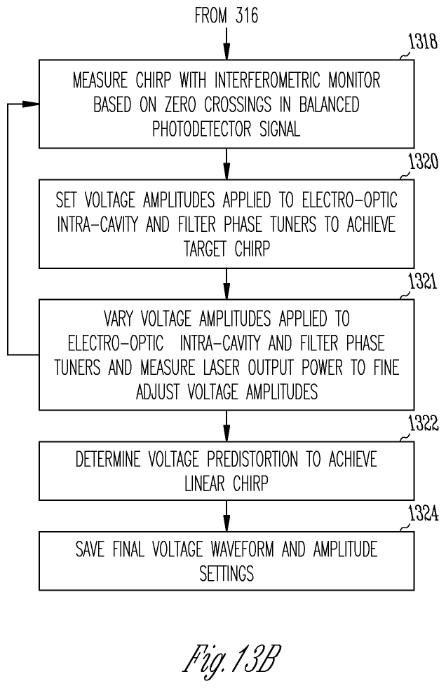

FIGS. 12A and 12B-12C are graphs of example initial and predistorted voltage waveforms applied to the electro-optic tuners of a chirped laser and the resulting chirp profiles, respectively, illustrating linearization of the chirp in accordance with various embodiments. As can be seen in FIG. 12A, the initial voltage waveform 1200 (solid line) is triangular, that is, linear in time in each half cycle. The resulting chirp is nonlinear, meaning that the laser frequency (or frequency shift relative to an initial frequency) varies nonlinearly over time, as shown by the measured chirp profile 1204 (solid line) in FIG. 12B. To calculate a predistortion for correcting the nonlinearity, a suitable analytical function, such as a polynomial (e.g., a third-order polynomial), is fitted to the measured data, as illustrated by the fitted chirp profile 1206 (dashed line). The roots of that fitted function can then be computed for different values of the frequency shift during the chirp, to determine the points in time at which the respective frequency shift was reached, and from that the associated applied voltage. For example, if the chirp has an amplitude of 20 GHz reached over a period of 2 μs, than the frequency shift at 1 μs would have to be 10 GHz for the chirp to be linear. Accordingly, the voltage that achieves 10 GHz, as determined from the fit, is to be applied at 1 μs. The analysis is repeated for a series of points along the fitted chirp profile (e.g., points equidistant in frequency shift across the entire chirp), and from the determined voltages at all points, the predistorted voltage waveform that achieves a linear chirp is constructed. FIG. 12A illustrates the corrected, predistorted voltage waveform 1202 (dotted line). FIG. 12C shows the measured chirp profile 1208, that is, the time-dependent frequency of the chirped signal after the predistorted voltage waveform 1202 has been applied (solid line). The measured chirp (solid line) is substantially more linear. The remaining small deviations from a linear fit 1210 (dashed line) can be corrected iteratively by repeating the predistortion computation until the measured linearity reaches a specified target.

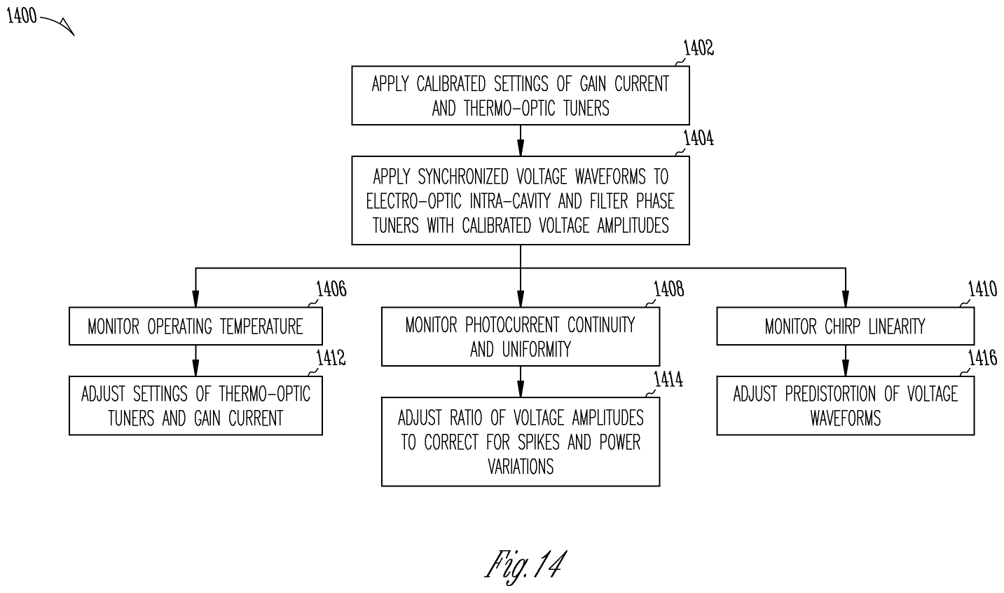

FIGS. 13A and 13B are two parts of a flowchart illustrating an example method 1300 of calibrating a chirped laser system 900, in accordance with various embodiments. It is assumed, for purposes of this example, that the laser has two wavelength filters (e.g., implemented with ring resonators 206, 208 or gratings 502, 504) with electro-optic and thermo-optic tuners, but the method 1300 can be straightforwardly adjusted to lasers that include only one wavelength filter, do not include thermo-optic and electro-optic phase tuners in both filters, or altogether omit thermo-optic phase tuners, by modifying or leaving out certain calibration operations, as will be obvious to those of ordinary skill in the art.

The method 1300 begins with the calibration of the gain current and thermo-optic settings. The electrical current to the laser gain section is turned on (at 1302), and the settings of the thermo-optic phase tuners of the wavelength filters are adjusted, e.g., via the electrical current applied to the respective heaters, to achieve a target wavelength (at 1304). If two wavelength filters each including a thermo-optic phase tuner are used, one of the thermo-optic phase tuners may be set to a mid-range value, and the heater current of the other thermo-optic phase tuner may be slowly increased until the target wavelength is reached. The electro-optic phase tuners, and any optional thermo-optic tuner in the cavity, are likewise set to mid-range values during this calibration. Then, the gain current may be adjusted to achieve a target optical power (at 1306). This calibration may be repeated for two or more different ambient temperatures, e.g., using a hot plate or other temperature-controlled device to change the temperature (at 1308). The temperature-dependent settings of the thermo-optic phase tuners and the gain section are saved to memory (at 1310) for future look-up. In some embodiments, the settings are determined at two temperatures within the expected range of operating temperatures, and the settings for one temperature are stored along with the change in settings per change in temperature, allowing the settings for any temperature within the range to be computed on the assumption of a liner temperature dependence. In some cases, the optical power at any given gain current does not depend significantly on the temperature; in that case, the gain-current calibration need be performed only once.

With the laser operating at the desired wavelength and output power, the electro-optic phase tuners are calibrated next. For that purpose, a triangular voltage waveform is applied, one at a time, to the electro-optic intra-cavity phase tuner or the electro-optic filter phase tuners, and the respective tuning efficiencies are measured based on the number of mode hops detected in the laser output power during the chirp, as described with respect to FIGS. 10A-10C. For example, in some embodiments, a voltage waveform of fixed amplitude ΔV is first applied to the electro-optic intra-cavity phase tuner, and the number of mode hops in each waveform period is determined and recorded as N_{cavity} (at 1312); the corresponding tuning efficiency of the intra-cavity phase tuner is proportional to, and may be saved as, N_{cavity}/ΔV. Then, the voltage waveform is removed from the intra-cavity phase tuner, synchronized triangular waveforms with amplitude ΔV are applied to both electro-optic filter phase tuners, and the number of mode hops per waveform period is measured and recorded as N_{filter} (at 1314); the corresponding tuning efficiency of the filter phase tuner is proportional to, and may be saved as, N_{filter}/ΔV. As will be apparent to those of ordinary skill in the art, the intra-cavity and filter phase tuners may, alternatively, be calibrated in the reverse order. Also, the voltage waveforms may, in principle, be different for both sets of tuners, as long as they are recorded along with the mode hop counts. After the relative tuning efficiencies have been calibrated, synchronized waveforms are applied to both the electro-optic intra-cavity phase tuner and the electro-optic filter phase tuners, with a ratio of the waveform amplitudes that is inverse to the ratio of the tuning efficiencies (at 1316). For example, if a voltage waveform with amplitude AV is applied to the intra-cavity phase tuner, then the amplitude of the voltage waveform applied to the filter phase tuners is ΔV·N_{cavity}/N_{filter}. This voltage ratio provides a near-equal frequency shift to all sections.

Next, the chirp resulting from the applied synchronized voltage waveforms is measured (at 1318), e.g., with an interferometric wavelength monitor by measuring a balanced photodetector signal at the output of an AMZI and determining, from the number of zero crossings, the number N of oscillations per chirp period, as explained above with reference to FIGS. 9 and 11A-11B. The chirp amplitude can be calculated as Δƒ_{chirp}=c/(n_{g}L)·N, and the waveform amplitudes applied to the phase tuners are adjusted (e.g., increased) by the same factor until the measured chirp amplitude matches the target chirp amplitude (at 1320). Since such scaling of the waveform amplitudes can slightly alter the relative tuning efficiencies of the electro-optic phase tuners, the voltage waveform amplitudes applied to the intra-cavity and filter phase tuners may, separately, be slightly varied around their initial calibrated values, and the uniformity of the laser output power as measured by the monitor photodiode may be observed to fine adjust the amplitudes (at 1321). Fine adjustments of the absolute and relative voltage waveforms may be repeated alternatingly the desired chirp amplitude and photocurrent uniformity are achieved. Finally, from the measured chirp, a voltage predistortion correcting for any non-linearity is determined (at 1322). The final voltage waveform and voltage amplitude setting are saved to memory (at 1324).

FIG. 14 is a flowchart illustrating an example method 1400 of operating a calibrated chirped laser system 900, in accordance with various embodiments. At the start of laser operation, the temperature is measured and the calibrated settings of the gain current and thermo-optic phase tuners are looked up in memory and applied (at 1402). This step may involve adjusting the settings stored for a certain calibration temperature based on the measured operating temperature and the stored change in settings per temperature offset. To chirp the laser, synchronized waveforms, which are likewise be looked up in memory (or, alternatively, determined from stored settings such as the tuning efficiencies and voltage amplitude for a target chirp amplitude), are applied to the electro-optic intra-cavity and filter phase tuners (at 1404); the ratio of the waveform amplitudes is inverse to the ratio of the tuning efficiencies. Further, throughout operation of the chirped laser, the temperature (at 1406), laser output power (at 1408), and chirp linearity (at 1410) may be measured. When a change in temperature is detected, the thermo-optic phase tuners and gain current are adjusted, based on the stored change in settings per temperature offset, to maintain the target optical power and alignment between the cavity mode and filter spectrum for single-mode lasing across temperature (at 1412). In addition, the photocurrent is monitored for continuity and uniformity, and fine adjustments to the electro-optic tuners in the filters are made to correct for and eliminate abrupt changes and spikes (at 1414). The measured chirp linearity is used to adjust the predistortion as needed to maintain a highly linear chirp profile (at 1416).

The following number examples are illustrative embodiments.
1. An integrated chirped laser comprising: a laser cavity defined between first and second reflective structures in a hybrid optical waveguide, the hybrid optical waveguide formed in part in a silicon device layer of a substrate and in part in one or more III-V waveguide sections disposed above the silicon device layer, the first and second reflective structures formed at least part in the silicon device layer; an optical gain section comprising a diode structure formed in one of the one or more III-V waveguide sections inside the laser cavity; an electro-optic phase-tuner formed inside the laser cavity; and a tunable optical wavelength filter forming at least part of the first reflective structure, the tunable optical wavelength filter comprising a thermo-optic filter phase tuner and an electro-optic filter phase tuner.
2. The integrated chirped laser of example 1, wherein the tunable optical wavelength filter is a first tunable optical wavelength filter, the integrated chirped laser further comprising: a second tunable optical wavelength filter comprising a thermo-optic filter phase tuner and an electro-optic filter phase tuner.
3. The integrated chirped laser of example 2, wherein the first and second tunable optical wavelength filters each comprise an optical ring resonator.
4. The integrated chirped laser of example 3, wherein the first optical ring resonator forms part of the first reflective structure and the second optical ring resonator forms part of the second reflective structure.
5. The integrated chirped laser of example 3, wherein the first and second optical ring resonators form part of the first reflective structure.
6. The integrated chirped laser of example 5, wherein the second reflective structure comprises a waveguide loop reflector.
7. The integrated chirped laser of example 5 or example 6, wherein the first and second optical ring resonators are each coupled between the hybrid optical waveguide and a shared resonator coupling waveguide such that: a portion of light coupled from the hybrid optical waveguide into the first optical ring resonator is coupled from the first optical ring resonator via the shared resonator coupling waveguide and the second optical ring resonator back into the hybrid optical waveguide, and a portion of light coupled from the hybrid optical waveguide into the second optical ring resonator is coupled from the second optical ring resonator via the shared resonator coupling waveguide and the first optical ring resonator back into the hybrid optical waveguide.
8. The integrated chirped laser of any of examples 3-7, wherein the first optical ring resonator has an associated free spectral range that differs from a free spectral range of the second optical ring resonator such that the first and second optical ring resonator together have an effective free spectral range greater than the free spectral ranges of the first and second optical ring resonators.
9. The integrated chirped laser of example 2, wherein the first tunable optical wavelength filter comprises a first grating forming the first reflective structure and the second tunable optical wavelength filter comprises a second grating forming the second reflective structure.
10. The integrated chirped laser of any of examples 1-9, wherein the tunable optical wavelength filter comprises a silicon waveguide structure formed in the silicon device layer and the electro-optic filter phase tuner comprises a p-n diode structure formed in a section of the silicon waveguide structure.
11. The integrated chirped laser of any of examples 1-10, wherein the tunable optical wavelength filter comprises a silicon waveguide structure formed in the silicon device layer and the electro-optic filter phase tuner comprises a p-n or p-i-n diode structure formed in a III-V waveguide section above the silicon waveguide structure.
12. The integrated chirped laser of any of examples 1-10, wherein the tunable optical wavelength filter comprises a waveguide structure formed in the silicon device layer and the thermo-optic filter phase tuner comprises a heater placed to heat a section of the waveguide structure.
13. The integrated chirped laser of any of examples 1-12, wherein the electro-optic phase tuner inside the laser cavity comprises a p-n diode structure formed in the silicon device layer.
14. The integrated chirped laser of any of examples 1-12, wherein the one or more III-V waveguide sections comprise first and second III-V waveguide sections, wherein the diode structure of the optical gain section is formed in the first III-V waveguide section, and wherein the electro-optic phase tuner inside the laser cavity comprises a p-n or p-i-n diode structure formed in the second III-V waveguide section.
15. The integrated chirped laser of any of examples 1-14, further comprising a thermo-optic phase-tuner formed inside the laser cavity.
16. An integrated chirped laser comprising: a laser cavity defined between first and second reflective structures in a hybrid optical waveguide, the hybrid optical waveguide formed in part in a silicon device layer of a substrate and in part in one or more III-V waveguide sections disposed above the silicon device layer, the first and second reflective structures formed at least part in the silicon device layer; an optical gain section comprising a diode structure formed in one of the one or more III-V waveguide sections inside the laser cavity; an electro-optic phase-tuner formed inside the laser cavity; and a first tunable optical wavelength filter comprising a first optical ring resonator and, in a section of the first ring resonator, a first filter phase tuner; a second tunable optical wavelength filter comprising a second optical ring resonator and, in section of the second ring resonator, a second filter phase tuner, wherein the first and second ring resonators form at least part of at least one of the first reflective structure or the second reflective structure.
17. The integrated chirped laser of example 16, wherein the first optical ring resonator forms part of the first reflective structure and the second optical ring resonator forms part of the second reflective structure.
18. The integrated chirped laser of example 16, wherein the first and second optical ring resonators form part of the first reflective structure, and wherein the first and second optical ring resonators are each coupled between the hybrid optical waveguide and a shared resonator coupling waveguide such that: a portion of light coupled from the hybrid optical waveguide into the first optical ring resonator is coupled from the first optical ring resonator via the shared resonator coupling waveguide and the second optical ring resonator back into the hybrid optical waveguide, and a portion of light coupled from the hybrid optical waveguide into the second optical ring resonator is coupled from the second optical ring resonator via the shared resonator coupling waveguide and the first optical ring resonator back into the hybrid optical waveguide.
19. The integrated chirped laser of example 18, wherein the second reflective structure comprises a waveguide loop reflector.
20. The integrated chirped laser of any of examples 16-19, wherein at least one of the first and second filter phase tuners is an electro-optic phase tuner.
21. The integrated chirped laser of any of examples 16-20, wherein at least one of the first and second filter phase tuners is a thermo-optic phase tuner.
22. The integrated chirped laser of any of examples 16-21, wherein the first and second filter phase tuners each comprise both an electro-optic phase tuner and a thermo-optic phase tuner.
23. A chirped laser system comprising: a laser comprising an optical gain section, an electro-optic intra-cavity phase tuner, and a tunable optical wavelength filter comprising an electro-optic filter phase tuner; photonic monitoring circuitry comprising: a monitor photodiode to measure a photocurrent indicative of an output power of laser light generated by the laser; and an interferometric wavelength monitor to measure a photocurrent indicative of a change in frequency of the laser light; and electronic control circuitry coupled to the photonic monitoring circuitry and the laser, the electronic control circuitry configured to chirp the frequency of the laser light by applying synchronized voltage waveforms to the electro-optic intra-cavity phase tuner and the electro-optic filter phase tuner, wherein: a ratio of amplitudes of the synchronized voltage waveforms applied to electro-optic intra-cavity phase tuner and the electro-optic filter phase tuner is set to an inverse of a ratio of tuning efficiencies of the electro-optic intra-cavity phase tuner and the electro-optic filter phase tuner as determined from the output power measured over a chirp period, and the amplitudes of the synchronized voltage waveforms applied to electro-optic intra-cavity phase tuner and the electro-optic filter phase tuner are scaled to achieve a target chirp amplitude as determined from the change in frequency of the laser light measured over the chirp period.
24. The chirped laser system of example 23, wherein the electronic control circuitry is further configured to predistort the synchronized voltage waveforms applied to the electro-optic intra-cavity phase tuner and the electro-optic filter phase tuner based on a chirp profile determined from the change in frequency of the laser light measured over the chirp period to linearize the chirp profile.
25. The chirped laser system of example 23 or example 24, wherein the electronic control circuitry is further configured to adjust, based on the measured photocurrent indicative of the output power of the laser light, a gain current applied to the optical gain section to achieve a target value of the output power.
26. The chirped laser system of any of examples 23-25, further comprising a semiconductor optical amplifier (SOA) at an output of the laser, wherein the electronic control circuitry is further configured to drive the SOA with a drive signal synchronized with the voltage waveforms applied to electro-optic intra-cavity phase tuner and the electro-optic filter phase tuner to reduce a variation in the output power over the chirp period.
27. The chirped laser system of any of examples 23-26, wherein the laser further comprises a thermo-optic filter phase tuner in the tunable optical wavelength filter, and wherein the electronic control circuitry is further configured to adjust a setting of the thermo-optic filter phase tuner based on a measured operating temperature to maintain alignment between a cavity mode of the laser and a filter spectrum of the tunable optical wavelength filter.
28. The chirped laser system of any of examples 23-27, wherein the interferometric wavelength monitor comprises an asymmetric Mach-Zehnder interferometer (AMZI) with a balanced photodetector at its output, the photocurrent indicative of the change in frequency of the laser light being a balanced photocurrent.
29. The chirped laser system of example 28, wherein the AMZI comprises a variable optical attenuator (VOA) in one of two waveguide arms of the AMZI, and wherein the electronic control circuitry is further configured to drive the VOA based on the balanced photocurrent to balance optical power between the two waveguide arms.
30. The chirped laser system of any of examples 23-29, wherein the laser and the photonic monitoring circuitry are implemented in a photonic integrated circuit (PIC).
31. The chirped laser system of any of examples 23-30, wherein the electronic control circuitry comprises a microprocessor configured to compute the ratio of the tuning efficiencies of the electro-optic intra-cavity phase tuner and the electro-optic filter phase tuner based on a number of negative spikes in the output power measured over the chirp period.
32. The chirped laser system of any of examples 23-31, wherein the photocurrent indicative of the change in frequency of the laser light is a balanced photocurrent, and wherein the electronic control circuitry comprises a microprocessor configured to compute the change in frequency of the laser light over the chirp period based on a number of zero crossings of the balanced photocurrent over the chirp period.
33. A method of calibrating a chirped laser comprising an optical gain section, an electro-optic intra-cavity phase tuner, and a tunable optical wavelength filter comprising an electro-optic filter phase tuner, the method comprising: applying a triangular voltage waveform to the electro-optic intra-cavity phase tuner and measuring a number of negative spikes in laser output power to determine a tuning efficiency of the electro-optic intra-cavity phase tuner; applying the triangular voltage waveform to the electro-optic filter phase tuner and measuring a number of negative spikes in laser output power to determine a tuning efficiency of the electro-optic filter phase tuner; applying, to the electro-optic intra-cavity phase tuner and the electro-optic filter phase tuner, synchronized triangular voltage waveforms with an amplitude ratio inverse to a ratio of the tuning efficiencies of the electro-optic intra-cavity phase tuner and the electro-optic filter phase tuner, and measuring a chirp of laser light output by the chirped laser; adjusting the synchronized triangular voltage waveforms applied to the electro-optic intra-cavity phase tuner and the electro-optic filter phase tuner in amplitude until a target chirp amplitude is reached; and saving the adjusted amplitudes of the synchronized triangular waveforms to memory.
34. The method of example 33, wherein the chirped laser comprises two tunable optical wavelength filters each comprising an electro-optic filter phase tuner, and wherein the tuning efficiency is determined for both electro-optic filter phase tuners simultaneously using synchronized triangular waveforms applied to the electro-optic filter phase tuners.
35. The method of example 33 or example 34, wherein the tunable optical wavelength filter further comprises a thermo-optic filter phase tuner, the method further comprising, prior to applying the triangular voltage waveform to the electro-optic intra-cavity phase tuner and the electro-optic filter phase tuner: calibrating, at two temperatures, a setting of the thermo-optic filter phase tuner to reach a target wavelength of the laser light output by the chirped laser, and saving the calibrated setting of the thermo-optic filter phase tuner to the memory.
36. The method of any of examples 33-35, further comprising, prior to applying the triangular voltage waveform to the electro-optic intra-cavity phase tuner and the electro-optic filter phase tuner: calibrating a value of a gain current applied to the optical gain section to achieve a target value of the laser output power, and saving the value of the calibrated gain current to the memory.
37. The method of any of examples 33-36, further comprising: fine-adjusting the amplitude ratio of the synchronized triangular voltage waveforms applied to the electro-optic intra-cavity phase tuner and the electro-optic filter phase tuner to improve uniformity of the laser output power over a chirp period.
38. The method of any of examples 33-37, further comprising: measuring a nonlinearity of the chirp; iteratively determining a predistortion on the synchronized triangular voltage waveforms that corrects for the nonlinearity; and storing the predistortion to the memory.
39. The method of any of examples 33-38, wherein measuring the chirp comprises: coupling the laser light into an asymmetric Mach-Zehnder interferometer (AMZI); and measuring a number of zero crossings of a balanced photocurrent measured at an output of the AMZI.
40. A method of operating a chirped laser comprising an optical gain section, an electro-optic intra-cavity phase tuner, and a tunable optical wavelength filter comprising an electro-optic filter phase tuner, the method comprising: applying a gain current to the optical gain section to generate laser light at an output of the chirped laser; and chirping a frequency of the laser light by applying synchronized voltage waveforms to the electro-optic intra-cavity phase tuner and the electro-optic filter phase tuner, wherein: a ratio of amplitudes of the synchronized voltage waveforms is set to an inverse of a calibrated ratio of tuning efficiencies of the electro-optic intra-cavity phase tuner and the electro-optic filter phase tuner, and the amplitudes of the synchronized voltage waveforms are scaled to achieve a target chirp amplitude.
41. The method of example 40, further comprising applying a predistortion to the synchronized voltage waveforms to correct for chirp nonlinearity.
42. The method of example 40 or example 41, further comprising measuring a power of the laser light, and adjusting the ratio of the amplitudes of the synchronized voltage waveforms to improve power uniformity over a chirp period.
43. The method of any of examples 40-42, wherein the tunable optical wavelength filter further comprises a thermo-optic filter phase tuner, the method further comprising: measuring a temperature of the chirped laser; and tuning the thermo-optic filter phase tuner to achieve a target wavelength of the laser light.
44. The method of any of examples 40-43, further comprising measuring a temperature of the chirped laser, and adjusting a setting of the gain current to achieve a target output power.
45. The method of any of examples 40-44, wherein the chirped laser comprises two tunable optical wavelength filters each comprising an electro-optic filter phase tuner, and wherein the synchronized voltage waveforms are applied to the electro-optic intra-cavity phase tuner and both electro-optic filter phase tuners.

Although embodiments have been described with reference to specific example embodiments, it will be evident that various modifications and changes may be made to these embodiments without departing from the broader scope of the disclosure. Accordingly, the specification and drawings are to be regarded in an illustrative rather than a restrictive sense.

What is claimed is:

1. An integrated chirped laser comprising:
a laser cavity defined between first and second reflective structures in a hybrid optical waveguide, the hybrid optical waveguide formed in part in a silicon device layer of a substrate and in part in one or more III-V waveguide sections disposed above the silicon device layer, the first and second reflective structures formed at least part in the silicon device layer;
an optical gain section comprising a diode structure formed in one of the one or more III-V waveguide sections inside the laser cavity;
an electro-optic phase-tuner formed inside the laser cavity; and
a tunable optical wavelength filter forming at least part of the first reflective structure, the tunable optical wavelength filter comprising a thermo-optic filter phase tuner and an electro-optic filter phase tuner.

2. The integrated chirped laser of claim 1, wherein the tunable optical wavelength filter is a first tunable optical wavelength filter, the integrated chirped laser further comprising:
a second tunable optical wavelength filter comprising a thermo-optic filter phase tuner and an electro-optic filter phase tuner.

3. The integrated chirped laser of claim 2, wherein the first and second tunable optical wavelength filters each comprise an optical ring resonator.

4. The integrated chirped laser of claim 3, wherein the first optical ring resonator forms part of the first reflective structure and the second optical ring resonator forms part of the second reflective structure.

5. The integrated chirped laser of claim 3, wherein the first and second optical ring resonators form part of the first reflective structure.

6. The integrated chirped laser of claim 5, wherein the first and second optical ring resonators are each coupled between the hybrid optical waveguide and a shared resonator coupling waveguide such that: a portion of light coupled from the hybrid optical waveguide into the first optical ring resonator is coupled from the first optical ring resonator via the shared resonator coupling waveguide and the second optical ring resonator back into the hybrid optical waveguide, and a portion of light coupled from the hybrid optical waveguide into the second optical ring resonator is coupled from the second optical ring resonator via the shared resonator coupling waveguide and the first optical ring resonator back into the hybrid optical waveguide.

7. The integrated chirped laser of claim 3, wherein the first optical ring resonator has an associated free spectral range that differs from a free spectral range of the second optical ring resonator such that the first and second optical ring resonator together have an effective free spectral range greater than the free spectral ranges of the first and second optical ring resonators.

8. The integrated chirped laser of claim 2, wherein the first tunable optical wavelength filter comprises a first grating forming the first reflective structure and the second tunable optical wavelength filter comprises a second grating forming the second reflective structure.

9. The integrated chirped laser of claim 1, wherein the tunable optical wavelength filter comprises a silicon waveguide structure formed in the silicon device layer and the electro-optic filter phase tuner comprises a p-n diode structure formed in a section of the silicon waveguide structure.

10. The integrated chirped laser of claim 1, wherein the tunable optical wavelength filter comprises a silicon waveguide structure formed in the silicon device layer and the electro-optic filter phase tuner comprises a p-n or p-i-n diode structure formed in a III-V waveguide section above the silicon waveguide structure.

11. The integrated chirped laser of claim 1, wherein the tunable optical wavelength filter comprises a waveguide structure formed in the silicon device layer and the thermo-optic filter phase tuner comprises a heater placed to heat a section of the waveguide structure.

12. The integrated chirped laser of claim 1, wherein the electro-optic phase tuner inside the laser cavity comprises a p-n diode structure formed in the silicon device layer.

13. The integrated chirped laser of claim 1, wherein the one or more III-V waveguide sections comprise first and second III-V waveguide sections, wherein the diode structure of the optical gain section is formed in the first III-V waveguide section, and wherein the electro-optic phase tuner inside the laser cavity comprises a p-n or p-i-n diode structure formed in the second III-V waveguide section.

14. The integrated chirped laser of claim 1, further comprising a thermo-optic phase-tuner formed inside the laser cavity.

15. An integrated chirped laser comprising:
a laser cavity defined between first and second reflective structures in a hybrid optical waveguide, the hybrid optical waveguide formed in part in a silicon device layer of a substrate and in part in one or more III-V waveguide sections disposed above the silicon device layer, the first and second reflective structures formed at least part in the silicon device layer;
an optical gain section comprising a diode structure formed in one of the one or more III-V waveguide sections inside the laser cavity;
an electro-optic phase-tuner formed inside the laser cavity;
a first tunable optical wavelength filter comprising a first optical ring resonator and, in a section of the first ring resonator, a first filter phase tuner; and
a second tunable optical wavelength filter comprising a second optical ring resonator and, in section of the second ring resonator, a second filter phase tuner,
wherein the first and second ring resonators form at least part of at least one of the first reflective structure or the second reflective structure.

16. The integrated chirped laser of claim 15, wherein the first optical ring resonator forms part of the first reflective structure and the second optical ring resonator forms part of the second reflective structure.

17. The integrated chirped laser of claim 15, wherein the first and second optical ring resonators form part of the first reflective structure, and wherein the first and second optical ring resonators are each coupled between the hybrid optical waveguide and a shared resonator coupling waveguide such that: a portion of light coupled from the hybrid optical waveguide into the first optical ring resonator is coupled from the first optical ring resonator via the shared resonator coupling waveguide and the second optical ring resonator back into the hybrid optical waveguide, and a portion of light coupled from the hybrid optical waveguide into the second optical ring resonator is coupled from the second optical ring resonator via the shared resonator coupling waveguide and the first optical ring resonator back into the hybrid optical waveguide.

18. The integrated chirped laser of claim 17, wherein the second reflective structure comprises a waveguide loop reflector.

19. The integrated chirped laser of claim 15, wherein at least one of the first and second filter phase tuners is an electro-optic phase tuner.

20. The integrated chirped laser of claim 15, wherein the first and second filter phase tuners each comprise both an electro-optic phase tuner and a thermo-optic phase tuner.
